(19) United States
(12) Patent Application Publication
(10) Pub. No.: US 2026/0372112 A1
(43) Pub. Date: Nov. 19, 2026

(54) SYSTEMS FOR VISIBLE WAVELENGTH MEASUREMENT OF OVERLAY OF WAFER-ON-WAFER BONDING AND METHODS OF FORMING THE SAME

(71) Applicant: Taiwan Semiconductor Manufacturing Company Limited, Hsinchu (TW)

(72) Inventors: Han-Jong Chia, Hsinchu City (TW); Chan-Wei Yeh, Hsinchu City (TW); Shih-Peng Tai, Xinpu Township (TW)

(21) Appl. No.: 19/748,250

(22) Filed: Jul. 21, 2026

Related U.S. Application Data
(62) Division of application No. 18/230,720, filed on Aug. 7, 2023.

(51) Int. Cl. H10W 46/00; H10W 20/00; H10W 80/00; H10W 90/00

(52) U.S. Cl. CPC H10W 46/00; H10W 20/01; H10W 46/301; H10W 80/312; H10W 80/327; H10W 90/792

(57) ABSTRACT

An embodiment method of forming a first wafer, which is a component of a wafer-to-wafer bonded structure, may include forming a plurality of electronic circuits in a semiconductor material layer of a substrate of the first wafer, forming an interconnect layer including electrical interconnect structures over the plurality of electronic circuits such that the electrical interconnect structures are electrically connected to the plurality of electronic circuits, forming a first dielectric window structure that extends through the semiconductor material layer and into the substrate, and removing a back-side portion of the substrate to reveal the first dielectric window structure. The method may further include placing the first wafer in proximity to a second wafer, directing visible light through the first dielectric window structure, and observing or recording an image, generated by the visible light, of first alignment marks of the first wafer and second alignment marks of the second wafer.

### CROSS-REFERENCE TO RELATED APPLICATIONS

This application is a divisional patent application of U.S. Application No. 18/230,720, entitled “Systems For Visible Wavelength Measurement of Overlay of Wafer-On-Wafer Bonding and Methods of Forming the Same” filed Aug. 7, 2023, which is hereby incorporated by reference in its entirety for all purposes.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers over a semiconductor substrate, and patterning the various material layers using lithography and etching to form circuit components and elements thereon. Dozens or hundreds of integrated circuits are typically manufactured on a single semiconductor wafer, and individual dies on the wafer are singulated by sawing between the integrated circuits along scribe lines. The individual dies are typically packaged separately, in multi-chip modules, or in other types of packaging, for example.

As semiconductor packages have become more complex, package sizes have tended to become larger to accommodate greater numbers of integrated circuits and/or dies per package. These larger and more complex semiconductor packages have created challenges in making effective and reliable interconnections among various components of the semiconductor package. As such, there is an ongoing need for improvements to semiconductor package designs with an emphasis on reducing interconnect lengths to thereby reduce ohmic loss, heat generation, and signal delay. One promising approach includes forming semiconductor packages at the wafer level by bonding one or more wafers containing semiconductor devices to one another.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a wafer-to-wafer bonded structure, according to various embodiments.

FIG. 2A is a vertical cross-sectional view of a structure after formation of complementary metal-oxide-semiconductor (CMOS) transistors, metal interconnect structures, and dielectric material layers, according to various embodiments.

FIG. 2B is a vertical cross-sectional view of a further structure during formation of a front-side interconnect structure, according to various embodiments.

FIG. 3A is a vertical cross-sectional view of an intermediate structure that may be used in the formation of devices on a semiconductor wafer, according to various embodiments.

FIG. 3B is a vertical cross-sectional view of a further intermediate structure that may be used in the formation of devices on a semiconductor wafer, according to various embodiments.

FIG. 3C is a vertical cross-sectional view of a further intermediate structure that may be used in the formation of devices on a semiconductor wafer, according to various embodiments.

FIG. 3D is a vertical cross-sectional view of a further intermediate structure that may be used in the formation of devices on a semiconductor wafer, according to various embodiments.

FIG. 4A is a vertical cross-sectional view of an intermediate structure that may be used in forming a first wafer, according to various embodiments.

FIG. 4B is a vertical cross-sectional view of a further intermediate structure that may be used in forming the first wafer, according to various embodiments.

FIG. 4C is a vertical cross-sectional view of a further intermediate structure that may be used in forming the first wafer, according to various embodiments.

FIG. 4D is a vertical cross-sectional view of a further intermediate structure that may be used in forming the first wafer, according to various embodiments.

FIG. 4E is a vertical cross-sectional view of a further intermediate structure that may be used in forming the first wafer, according to various embodiments.

FIG. 4F is a vertical cross-sectional view of a further intermediate structure that may be used in forming the first wafer, according to various embodiments.

FIG. 5A is a vertical cross-sectional view of a further intermediate structure that may be used in forming the first wafer, according to various embodiments.

FIG. 5B is a vertical cross-sectional view of a further intermediate structure that may be used in forming the first wafer, according to various embodiments.

FIG. 5C is a vertical cross-sectional view of a further intermediate structure that may be used in forming the first wafer, according to various embodiments.

FIG. 6A is a vertical cross-sectional view of an intermediate structure that may be used in forming a second wafer, according to various embodiments.

FIG. 6B is a vertical cross-sectional view of a further intermediate structure that may be used in forming the second wafer, according to various embodiments.

FIG. 6C is a vertical cross-sectional view of the second wafer formed by further processing the intermediate structure of FIG. 6B, according to various embodiments.

FIG. 7A is a vertical cross-sectional view of an intermediate structure in which a first wafer is positioned in proximity to a second wafer prior to forming a wafer-to-wafer bonded structure, according to various embodiments.

FIG. 7B is a vertical cross-sectional view of a wafer-to-wafer bonded structure formed by bonding the first wafer and the second wafer of FIG. 7A, according to various embodiments.

FIG. 8A is a vertical cross-sectional view of a further intermediate structure that includes the wafer-to-wafer bonded structure of FIG. 7B, according to various embodiments.

FIG. 8B is a vertical cross-sectional view of an intermediate structure in which a third wafer is positioned in proximity the first wafer prior to forming a further wafer-to-wafer bonded structure, according to various embodiments.

FIG. 8C is a vertical cross-sectional view of a further wafer-to-wafer bonded structure formed by bonding the third wafer and the first wafer of FIG. 8B, according to various embodiments.

FIG. 8D is a vertical cross-sectional view of a further intermediate structure that includes the wafer-to-wafer bonded structure of FIG. 8C, according to various embodiments.

FIG. 9A is a vertical cross-sectional view of an intermediate structure that may be used in forming a first wafer, according to various embodiments.

FIG. 9B is a vertical cross-sectional view of a further intermediate structure that may be used in forming the first wafer, according to various embodiments.

FIG. 9C is a vertical cross-sectional view of a further intermediate structure that may be used in forming the first wafer, according to various embodiments.

FIG. 9D is a vertical cross-sectional view of a further intermediate structure that may be used in forming the first wafer, according to various embodiments.

FIG. 9E is a vertical cross-sectional view of a further intermediate structure that may be used in forming the first wafer, according to various embodiments.

FIG. 9F is a vertical cross-sectional view of a further intermediate structure that may be used in forming the first wafer, according to various embodiments.

FIG. 10A is a vertical cross-sectional view of a further intermediate structure that may be formed by further processing the intermediate structure of FIG. 9F, according to various embodiments.

FIG. 10B is a vertical cross-sectional view of a further intermediate structure that may be used in forming the first wafer, according to various embodiments.

FIG. 11A is a vertical cross-sectional view of a further intermediate structure that may be used in forming the first wafer, according to various embodiments.

FIG. 11B is a vertical cross-sectional view of a further intermediate structure that may be used in forming the first wafer, according to various embodiments.

FIG. 12A is a vertical cross-sectional view of an intermediate structure in which a first wafer is positioned in proximity to a second wafer prior to forming a wafer-to-wafer bonded structure, according to various embodiments.

FIG. 12B is a vertical cross-sectional view of a wafer-to-wafer bonded structure formed by bonding the first wafer and the second wafer of FIG. 12A, according to various embodiments.

FIG. 13 is a flowchart illustrating operations of a method of forming a wafer-to-wafer bonded structure, according to various embodiments.

FIG. 14 is a flowchart illustrating operations of a further method of forming a wafer-to-wafer bonded structure, according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Wafer-on-wafer (WoW) bonding may be implemented to provide increasingly smaller devices. Stacking wafers of logic-logic, logic-memory, or memory-memory devices may increase the number of transistors per unit area while also reducing overall power consumption by reducing interconnect distances. Current WoW structures have bond pitches in a range from 1 to 20 microns. Systems exhibiting sub-micron bond pitches may be advantageous for future applications. However, one of the difficulties in achieving smaller bond pitch is the challenge posed by the desire to observe alignment and overlay marks accurately before and after wafer bonding, respectively. Unlike alignment in photolithography, where a lens has an unobstructed view of the alignment marks, typical WoW bonding requires measuring locations of alignment marks of each wafer separately, storing the position data in a tool computer, and then moving the wafers together based on the stored position. Due to the size of the optical lens, which must be moved out of the way before bonding, this entails moving the wafers over 10s-100s of millimeters which may result in positioning errors of ~50 nm over travel distances of this range.

After bonding is complete, to measure the overlay, imaging systems may be required to image bonding marks through various thicknesses of silicon (e.g., tens to hundreds of microns). Currently, infrared wavelengths above 1000 nm are used because such wavelengths may penetrate through a silicon wafer. However, the relatively long wavelength of infrared light limits the resolution of infrared radiation. In this regard, infrared radiation has roughly twice the wavelength of visible light and thus has a resolution roughly two times worse than visible light. As a result, WoW alignment and overlay errors may exceed that of photolithography and may make it difficult to reach alignment and overlay below 20 nm.

The various embodiments disclosed herein may be advantageous by providing systems and methods to create a direct line of sight to observe alignment marks on respective wafers using visible light. In this regard, various embodiment wafers disclosed herein for wafer-to-wafer bonding may include one or more dielectric windows that may allow visible light to be transmitted through the dielectric window such that alignment marks may be imaged with the visible light. The use of visible light may improve alignment and overlay. In this regard, alignment may be performed while a first wafer and a second wafer are within close proximity to one another. As such, the use of visible light may allow up to a two-fold increase in the resolution of alignment marks leading to improved alignment and overlay characterization.

An embodiment method of forming a first wafer, which is a component of a wafer-to-wafer bonded structure, may include forming a plurality of electronic circuits in a semiconductor material layer of a substrate of the first wafer, forming an interconnect layer including electrical interconnect structures over the plurality of electronic circuits such that the electrical interconnect structures are electrically connected to the plurality of electronic circuits, forming a first dielectric window structure that extends through the semiconductor material layer and into the substrate, and removing a back-side portion of the substrate to reveal the first dielectric window structure. The method may further include forming a via structure that is electrically connected to the electrical interconnect structures and extends into the semiconductor material layer, such that the process of removing the back-side portion of the substrate further reveals the via structure.

A further embodiment method of forming a wafer-to-wafer bonded structure may include placing a first wafer, including first electrical circuits, in proximity to a second wafer, including second electrical circuits, such that first bond pad structures of the first wafer are approximately aligned with second bond pad structures of the second wafer, and determining a position of one or more first alignment marks of the first wafer relative to one or more second alignment marks of the second wafer by imaging one or more first alignment marks and the second alignment marks through a first dielectric window structure formed in the first wafer. The method may further include adjusting a relative position of the first wafer and the second wafer to align the one or more first alignment marks of the first wafer relative to the one or more second alignment marks of the second wafer based on imaging of the one or more first alignment marks and the one or more second alignment marks through the first dielectric window structure, placing the first wafer in contact with the second wafer such that the first bond pad structures of the first wafer are contacting the second bond pad structures of the second wafer, and performing a direct bonding process to bond the first wafer to the second wafer.

An embodiment wafer-to-wafer bonded structure may include a first wafer including first electrical circuits electrically connected to first bond pad structures, a first dielectric window structure, and first alignment marks aligned with the first dielectric window structure in a plan view. The embodiment wafer-to-wafer bonded structure may further include a second wafer including second electrical circuits electrically connected to second bond pad structures, and second alignment marks. The first wafer may be directly bonded to the second wafer such that the first bond pad structures are electrically connected to the second bond pad structures and the first alignment marks are aligned relative to the second alignment marks. The first dielectric window structure may be configured to be transparent to visible light allowing imaging of the first alignment marks and the second alignment marks using the visible light.

As used herein, a “back-end-of-line” component or a “BEOL” component refers to any component that is formed at a contact level or at a metal interconnect level. A “metal interconnect level” refers to a level through which a metal interconnect structure such as a metal line or a metal via structure vertically extends. As used herein, a “front-end-of-line” component or an “FEOL” component refers to any component that is formed prior to formation of any contact level structure, if followed by formation of contact level structures, or without formation of any contact level structure or any metal interconnect structure (i.e., not followed by formation of any contact level structure or any metal interconnect structure).

In general, FEOL components refer to semiconductor device components that may be formed during a CMOS manufacturing process prior to formation of any contact via structure on nodes of field effect transistors, and BEOL components refer to semiconductor device components that may be formed during a CMOS manufacturing process during, or after, the earliest contact via formation process that forms contact via structures on nodes of field effect transistors. In embodiments in which any embodiment manufacturing steps are integrated into a CMOS manufacturing process, a component formed prior to formation of any contact via structure on nodes of field effect transistors may be referred to as an FEOL component, and a component formed during, or after, the earliest contact via formation process that forms contact via structures on nodes of field effect transistors may be referred to as a BEOL component.

Generally, an FEOL component may be formed within a semiconductor substrate, directly on a semiconductor substrate, or indirectly on a semiconductor substrate without any intervening metal interconnect structure between the semiconductor substrate and the component. Examples of the FEOL components include planar field effect transistors using a portion of the semiconductor substrate as a portion of a channel, fin field effect transistors (FinFET), gate-all-around field effect transistors, and any device component that includes a portion of a semiconductor substrate that has a lateral extent greater than the lateral extent of the respective device component. Typically, for each FEOL component, no metal interconnect structure vertically extends from a first horizontal plane including a top surface of the FEOL component to a second horizontal plane including a bottom surface of the FEOL component, or the FEOL component contacts, or is laterally surrounded by, a semiconductor material layer having a greater lateral extent than the FEOL component.

Examples of the BEOL components may include any dielectric material layer embedding a metal via structure or embedding a metal line structure, any metal interconnect structure, memory cells formed without using any portion of a semiconductor substrate, selector cells formed without using any portion of a semiconductor substrate, thin film transistors formed without using any portion of a semiconductor substrate (but may include patterned semiconductor material portions having a lateral extent that does not exceed the lateral extent of an individual thin film transistor or a cluster of merged thin film transistors), and bonding pads. Typically, for each BEOL component, at least one metal interconnect structure vertically extends from a first horizontal plane including a top surface of the BEOL component to a second horizontal plane including a bottom surface of the BEOL component, and the BEOL component does not contact, and is not laterally surrounded by, a semiconductor material layer having a greater lateral extent than the BEOL component.

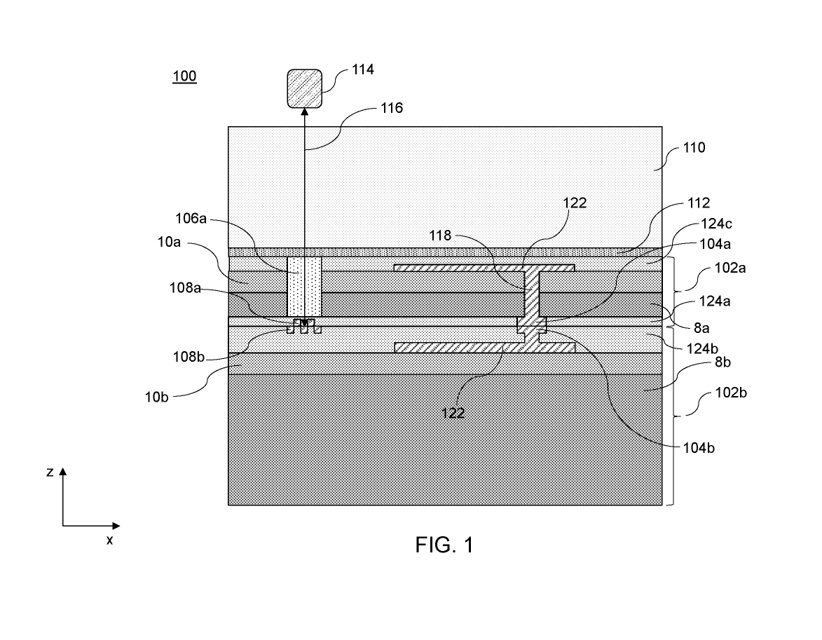

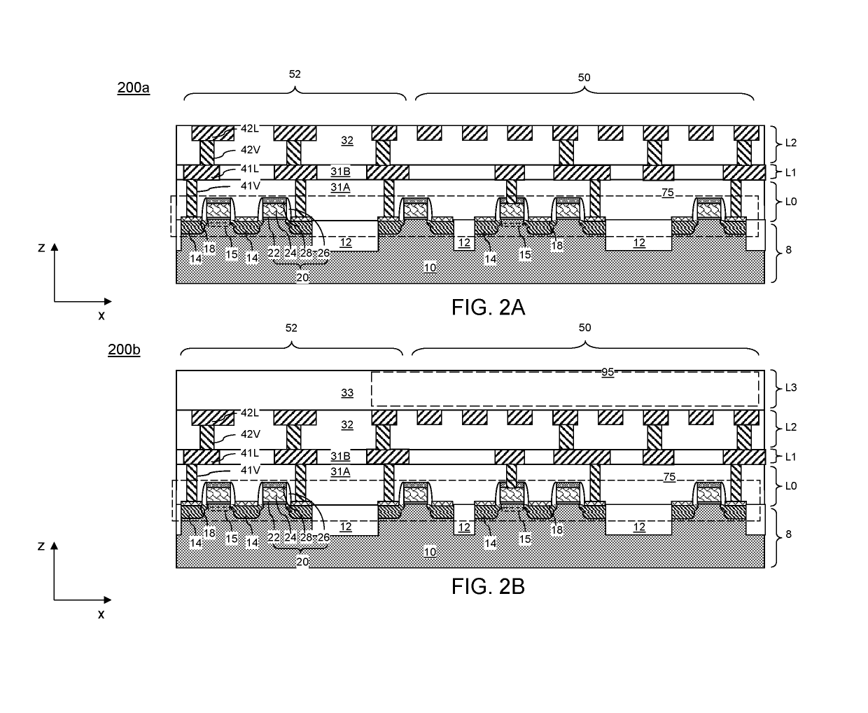

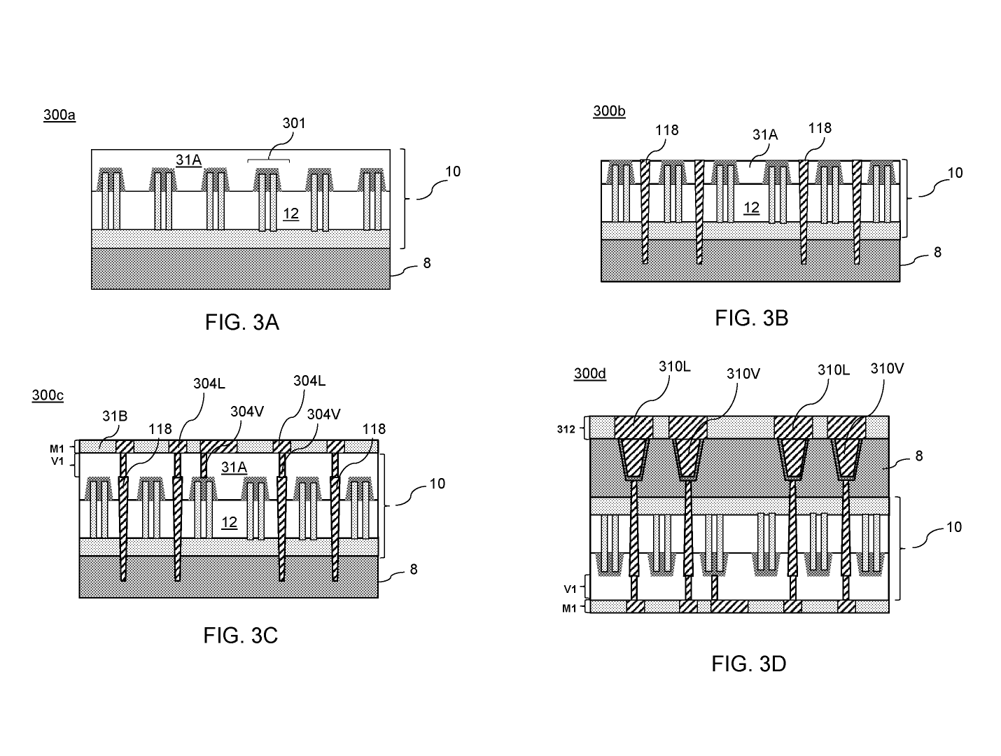

FIG. 1 is a vertical cross-sectional view of a wafer-to-wafer bonded structure 100, according to various embodiments. The wafer-to-wafer bonded structure 100 may include a first wafer 102a bonded to a second wafer 102b. The first wafer 102a may include first electrical circuits (e.g., see CMOS circuits 75 in FIGS. 2A and 2B, FinFET transistors 301 in FIG. 3A, etc.) formed in a first semiconductor material layer 10a of a first substrate 8a. The first electrical circuits (75, 301) may be electrically connected to first bond pad structures 104a. The first wafer 102a may further include a first dielectric window structure 106a and first alignment marks 108a. As shown in FIG. 1, the first alignment marks 108a may be aligned with the first dielectric window structure 106a in a plan view (e.g., when viewed along the z-direction in FIG. 1).

In the example embodiment of FIG. 1, the first wafer 102a may be temporarily adhered to a carrier substrate 110 with an adhesive 112. The carrier substrate 110 may be chosen to be a material that is transparent to visible light. The adhesive 112 may be configured to be decoupled from the carrier substrate 110 and the first wafer 102a by application of heat or ultraviolet radiation (i.e., UV-light). The first dielectric window structure 106a may be configured to be transparent to visible light 116. As such, an optical system 114 may be used to image the first alignment marks 108a relative to second alignment marks 108b of the second wafer 102b by transmitting and receiving visible light 116 through the first dielectric window structure 106a. In this regard, the first dielectric window structure 106a may be formed of a material that is transparent to visible light, such as silicon dioxide. Other transparent materials may be used to form the first dielectric window structure 106a in other embodiments. The use of visible light 116 may allow more accurate positioning of the first wafer 102a relative to the second wafer 102b in comparison with alternative embodiments that do not include the first dielectric window structure 106a.

The second wafer 102b may include second electrical circuits (e.g., see CMOS circuits 75 in FIGS. 2A and 2B, FinFET transistors 301 in FIG. 3A, etc.) formed in a second semiconductor material layer 10b over a second substrate 8b. The second electrical circuits 75 may be electrically connected to second bond pad structures 104b. The first wafer 102a may be directly bonded to the second wafer 102b such that the first bond pad structures 104a are electrically connected to the second bond pad structures 104b and the first alignment marks 108a are aligned relative to the second alignment marks 108b.

As shown in FIG. 1, the first wafer 102a may be bonded to the second wafer 102b in a face-to-back configuration. In this regard, the first bond pad structures 104a may be configured as back-side bond pad structures 104a formed in a first dielectric layer 124a on a back side of the first substrate 8a of the first wafer 102a. As such, the back-side bond pad structures 104a may be electrically connected to a via structure 118 that is formed in the first semiconductor material layer 10a and penetrates through the first substrate 8a. The via structure 118 may also be configured to be electrically connected to the first electrical circuits (75, 301). As further shown in FIG. 1, the second bond pad structures 104b may be configured as front-side bond pad structures 104b formed in a second dielectric layer 124b on a front side of the second wafer 102b. The front-side bond pad structures 104b may be electrically connected to electrical interconnect structures 122 of the second wafer 102b. The first wafer 102a may further include additional front-side electrical interconnect structures 122 formed within a third dielectric layer 124c.

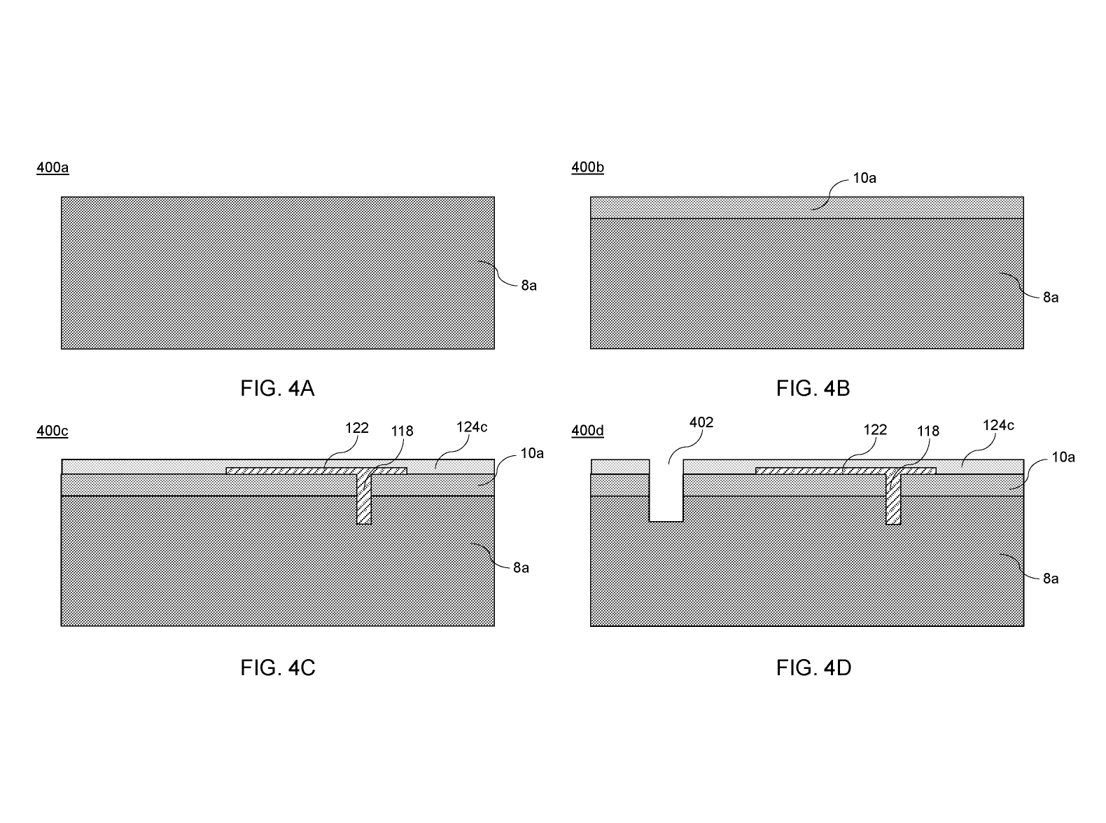

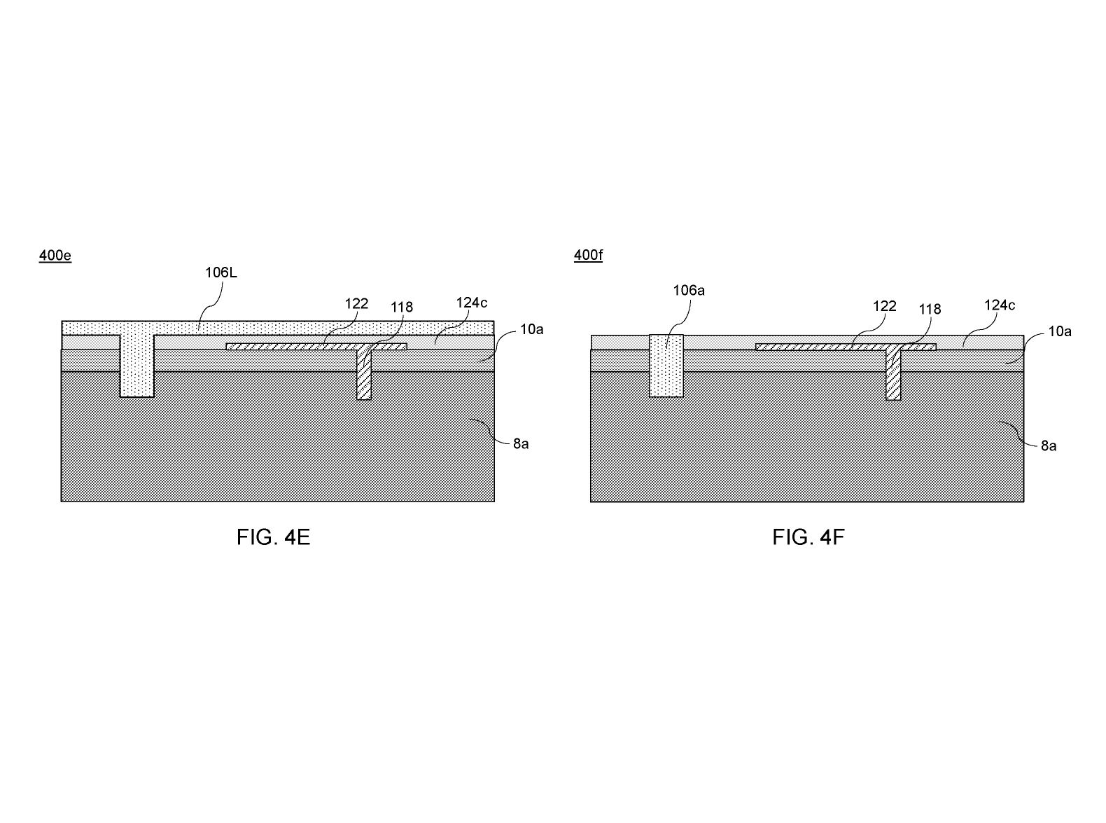

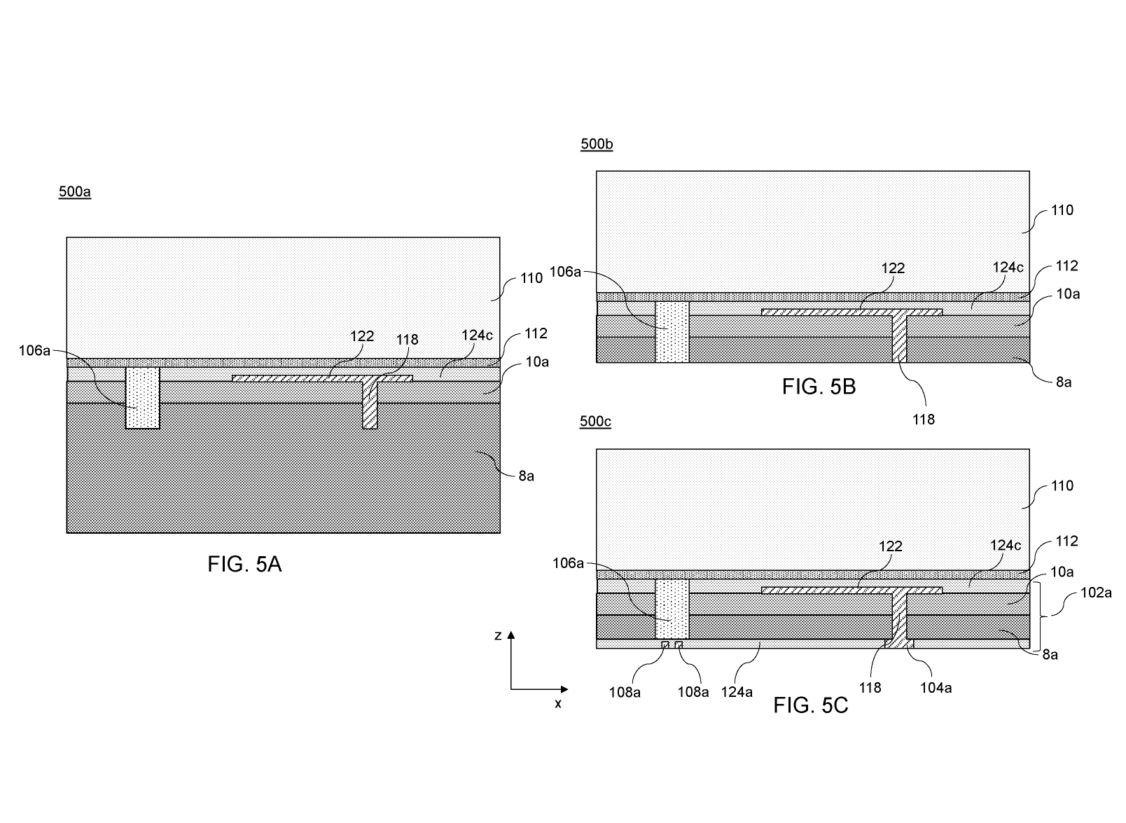

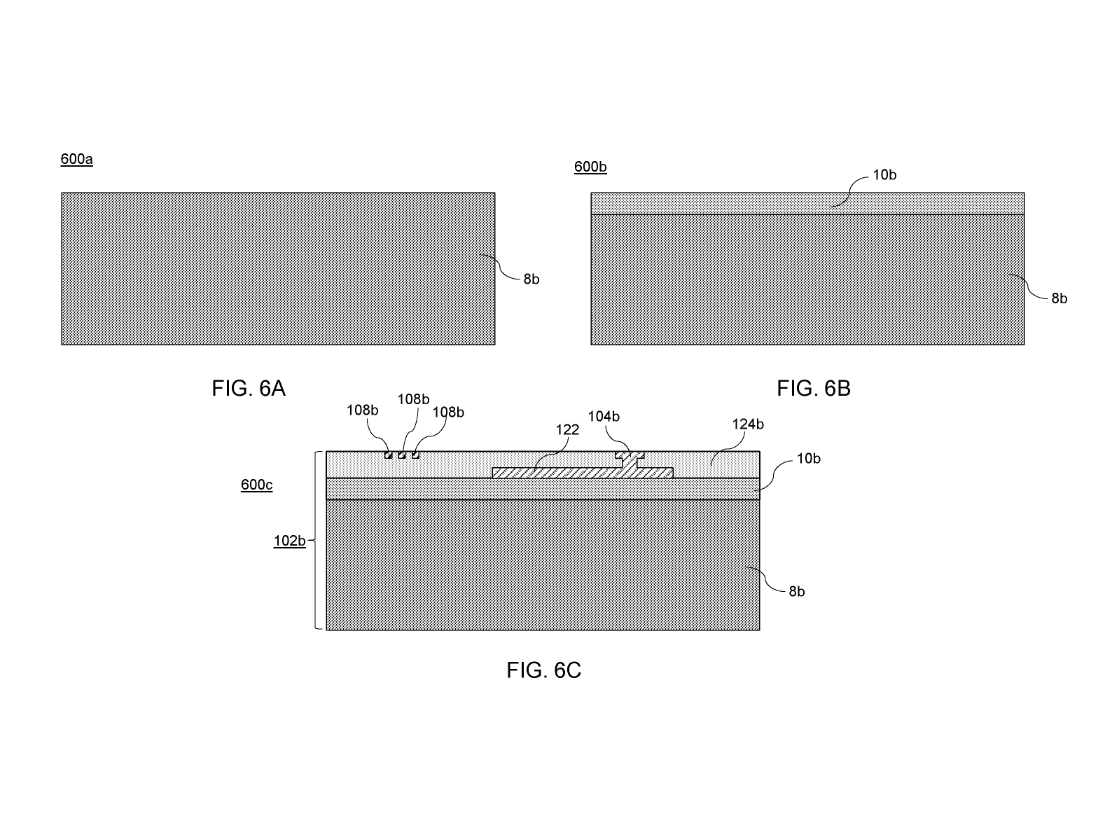

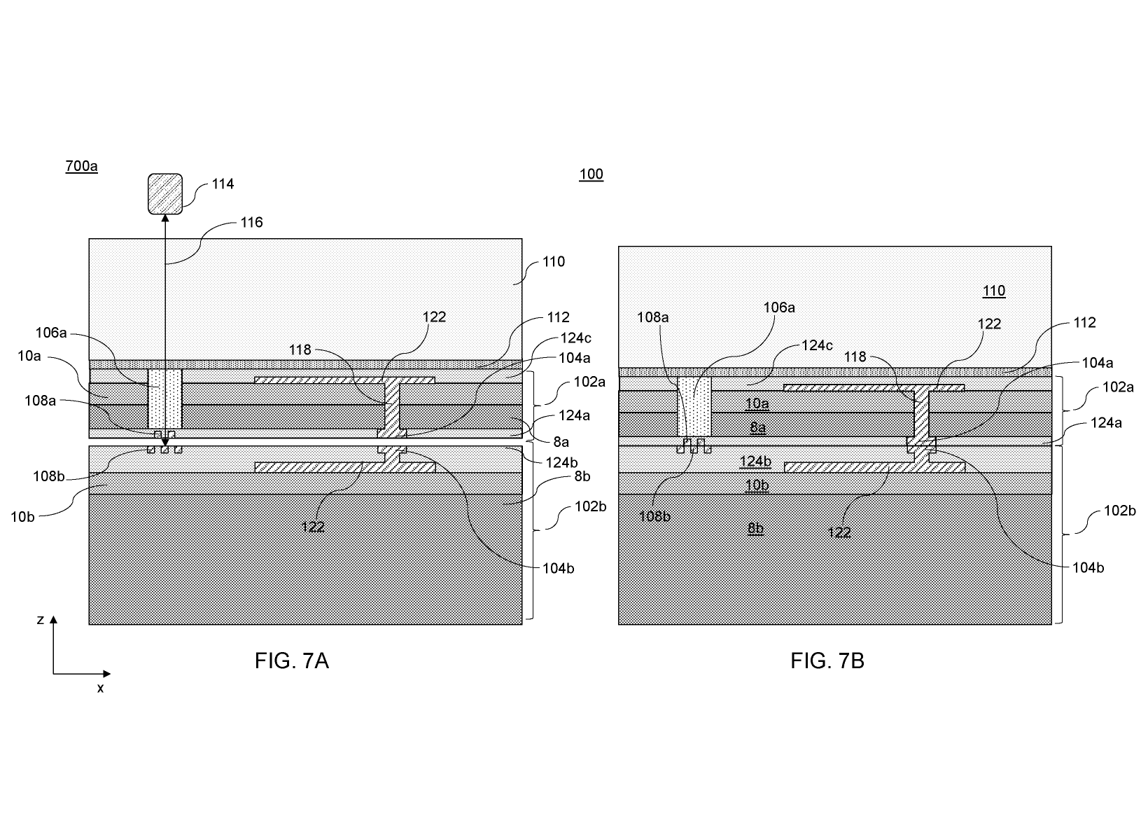

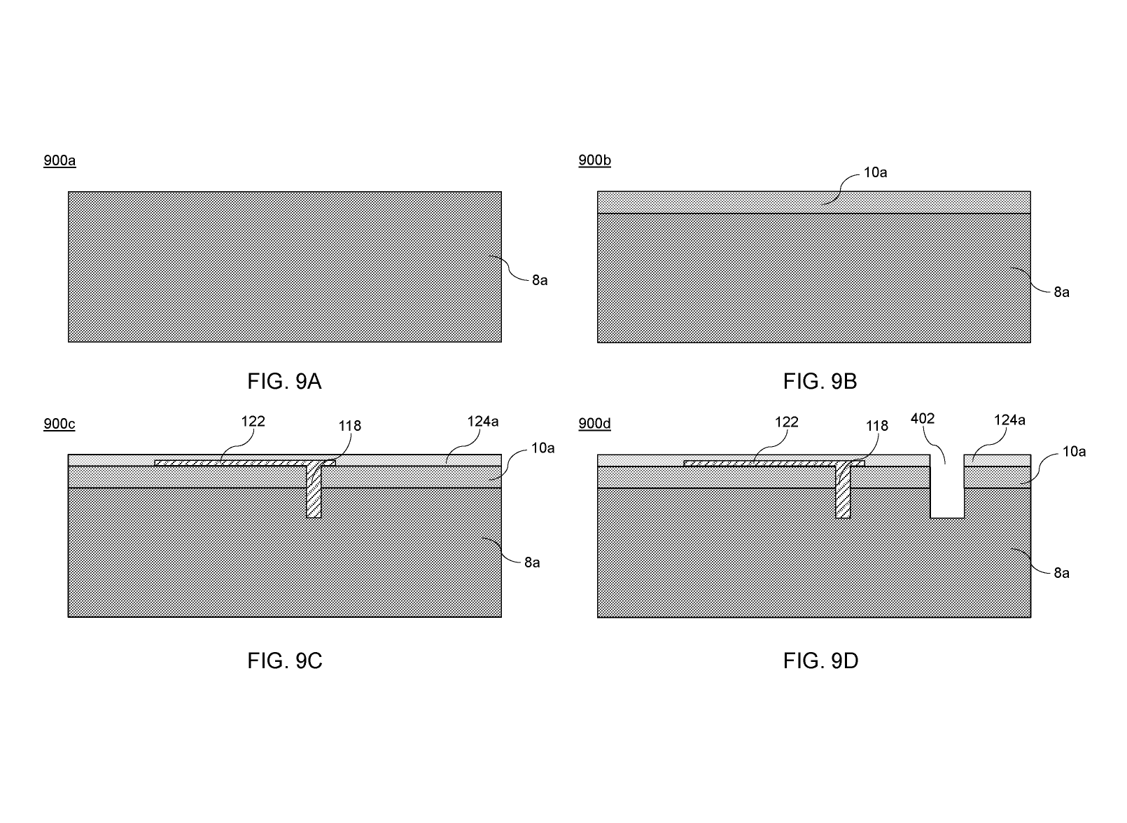

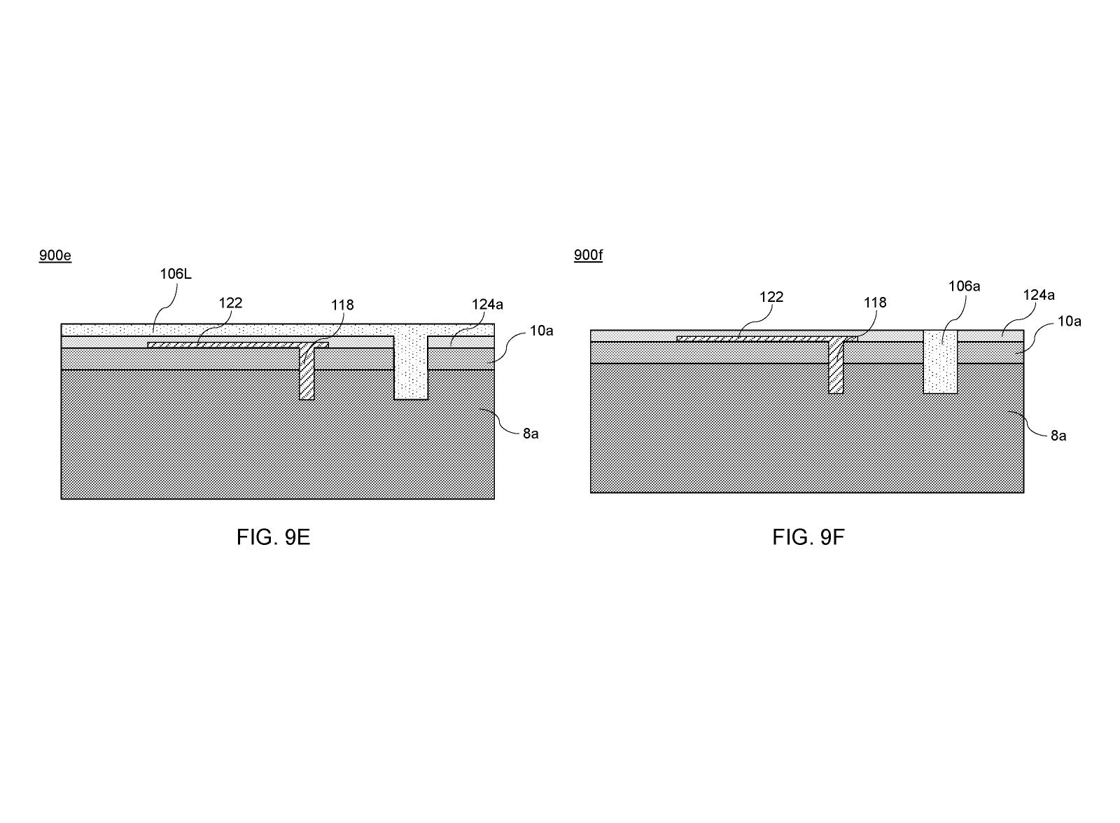

The first alignment marks 108a and the first bond pad structures 104a may be formed in the first dielectric layer 124a, as shown in FIG. 1. Similarly, the second alignment marks 108b and the second bond pad structures 104b may be formed in the second dielectric layer 124b. The first wafer 102a may be bonded to the second wafer 102b by performing a hybrid bonding process such that direct dielectric-to-dielectric bonds may be formed between the first dielectric layer 124a and the second dielectric layer 124b. Similarly, the hybrid bonding process may generate direct metal-to-metal bonds between the first bond pad structures 104a and the second bond pad structures 104b. The formation of the first wafer 102a is described in greater detail with reference to FIGS. 4A-5C, below, and the formation of the second wafer 102b is described in greater detail with reference to FIGS. 6A-6C, below. A process of aligning and bonding the first wafer 102a to the second wafer 102b in the face-to-back configuration of FIG. 1 is described in greater detail with reference to FIGS. 7A and 7B, below. In various other embodiments, the first wafer 102a may be bonded to the second wafer 102b in a fact-to-face configuration as described in greater detail with reference to FIGS. 9A-12B, below.

FIG. 2A is a vertical cross-sectional view of an intermediate structure 200a after formation of complementary metal-oxide-semiconductor (CMOS) transistors, metal interconnect structures, and dielectric material layers, according to various embodiments. The intermediate structure 200a is an example of a structure that may be used to form the first and second electrical circuits 75 in the first wafer 102a and the second wafer 102b, respectively, as described above. The intermediate structure 200a may include a substrate 8, which may be a semiconductor substrate such as a commercially available silicon substrate. The substrate 8 may include a semiconductor material layer 10 at least at an upper portion thereof. The substrate 8 may include a bulk semiconductor substrate such as a silicon substrate in which the semiconductor material layer 10 continuously extends from a top surface of the substrate 8 to a bottom surface of the substrate 8, or a semiconductor-on-insulator (SOI) layer including the semiconductor material layer 10 as a top semiconductor layer overlying a buried insulator layer (such as a silicon oxide layer). The structure may include various device regions 50 in which devices may be subsequently formed.

The structure may also include a peripheral logic region 52 in which electrical connections between various devices and various peripheral circuits including field effect transistors may be subsequently formed. Semiconductor devices such as field effect transistors (FETs) may be formed on, and/or in, the semiconductor material layer 10 during a FEOL operation. For example, shallow trench isolation structures 12 may be formed in an upper portion of the semiconductor material layer 10 by forming shallow trenches and subsequently filling the shallow trenches with a dielectric material such as silicon oxide. Other suitable dielectric materials are within the contemplated scope of disclosure. Various doped wells (not expressly shown) may be formed in various regions of the upper portion of the semiconductor material layer 10 by performing masked ion implantation processes.

Gate structures 20 may be formed over the top surface of the substrate 8 by depositing and patterning a gate dielectric layer, a gate electrode layer, and a gate cap dielectric layer. Each gate structure 20 may include a vertical stack of a gate dielectric 22, a gate electrode 24, and a gate cap dielectric 28, which is herein referred to as a gate stack (22, 24, 28). Ion implantation processes may be performed to form extension implant regions, which may include source extension regions and drain extension regions. Dielectric gate spacers 26 may be formed around the gate stacks (22, 24, 28). Each assembly of a gate stack (22, 24, 28) and a dielectric gate spacer 26 may constitute a gate structure 20. Additional ion implantation processes may be performed that use the gate structures 20 as self-aligned implantation masks to form deep active regions.

Such deep active regions may include deep source regions and deep drain regions. Upper portions of the deep active regions may overlap with portions of the extension implantation regions. Each combination of an extension implantation region and a deep active region may constitute a source/drain region 14 depending on electrical biasing. A semiconductor channel 15 may be formed underneath each gate stack (22, 24, 28) between a neighboring pair of source/drain regions 14. Metal-semiconductor alloy regions 18 may be formed on the top surface of each source/drain region 14.

Field effect transistors may be formed on the semiconductor material layer 10. Each field effect transistor may include a gate structure 20, a semiconductor channel 15, a pair of source/drain regions 14 (one of which functions as a source region and another of which functions as a drain region), and optional metal-semiconductor alloy regions 18. CMOS circuits 75 may be provided on the semiconductor material layer 10, which may include a periphery circuit for the array(s) of transistors, such as thin film transistors (TFTs), and phase-change material (PCM) switches etc.

In one embodiment, the substrate 8 may include a single crystalline silicon substrate, and the CMOS circuits 75 may include a respective portion of the single crystalline silicon substrate as a semiconducting channel. As used herein, a “semiconducting” element refers to an element having electrical conductivity in the range from 1.0 x 10-6 S/cm to 1.0 x 105 S/cm. As used herein, a “semiconductor material” refers to a material having electrical conductivity in the range from 1.0 x 10-6 S/cm to 1.0 x 105 S/cm in the absence of electrical dopants therein and is capable of producing a doped material having electrical conductivity in a range from 1.0 S/cm to 1.0 x 105 S/cm upon suitable doping with an electrical dopant.

Various interconnect-level structures may be subsequently formed, which may form the front-side interconnect layer, described above. The interconnect-level structures may be referred to as lower interconnect-level structures (L0, L1, L2) and may be formed before any additional BEOL devices, such as additional memory devices. In some embodiments, one or more additional devices may be formed over one or more levels of interconnect-level metal lines. For example, the one or more additional devices may include TFTs, memory devices, or PCM switches.

The lower interconnect-level structures (L0, L1, L2) may include a contact-level structure L0, a first interconnect-level structure L1, and a second interconnect-level structure L2. The contact-level structure L0 may include a planarization dielectric layer 31A including a planarizable dielectric material such as silicon oxide and various contact via structures 41V contacting a respective one of the source/drain regions 14 or the gate electrodes 24 and formed within the planarization dielectric layer 31A.

The first interconnect-level structure L1 may include a first interconnect level dielectric (ILD) layer 31B and first metal lines 41L formed within the first ILD layer 31B. The first ILD layer 31B is also referred to as a first line-level dielectric layer. The first metal lines 41L may contact a respective one of the contact via structures 41V. The second interconnect-level structure L2 may include a second ILD layer 32 and a stack of a first via-level dielectric material layer and a second line-level dielectric material layer or a line-and-via-level dielectric material layer. The second ILD layer 32 may include second interconnect-level metal interconnect structures (42V, 42L) there within, which includes first metal via structures 42V and second metal lines 42L. Top surfaces of the second metal lines 42L may be coplanar with the top surface of the second ILD layer 32.

FIG. 2B is a vertical cross-sectional view of a further intermediate structure 200b during formation of one or more additional BEOL devices (e.g., phase-change material switch, a memory device, etc.), according to various embodiments. The one or more additional BEOL devices may be formed in the device region 50 over the second interconnect-level structure L2. A third ILD layer 33 may be formed during formation of one or more additional BEOL devices 95. The set of all structures formed at the level of the one or more BEOL devices 95 may be referred to as a third interconnect-level structure L3. Various additional interconnect layers may be formed over the intermediate structure 200b as needed, based on circuit design considerations, in other embodiments.

FIGS. 3A-3D are vertical cross-sectional views of intermediate structures (300a, 300b, 300c, 300d) that may be used in the formation of the first wafer 102a, according to various embodiments. The intermediate structure 300a may include a semiconductor material layer 10 having a plurality of transistor structures 301 formed on a semiconductor substrate 8 in an FEOL process, as described above with reference to FIGS. 2A and 2B. In this example embodiment, the transistor structures 301 are illustrated as FinFET transistors, however, other types of transistor structures may be formed in the semiconductor material layer 10. For example, in other embodiments, the semiconductor material layer 10 may include CMOS circuits 75, as described above with reference to FIGS. 2A and 2B. Each of the transistor structures 301 may be separated from one another by a plurality of shallow trench isolation structures 12. The intermediate structure 300a may further include a planarization dielectric layer 31A including a planarizable dielectric material such as silicon oxide.

The intermediate structure 300b of FIG. 3B may be formed from the intermediate structure 300a of FIG. 3A by removing a top portion of the planarization dielectric layer 31A above top surfaces of the transistor structures 301 and by forming via structures 118 through the semiconductor material layer 10. As shown, the via structures 118 may be formed in the shallow trench isolation structures 12 in regions between the transistor structures 301. The via structures 118 may have a width that is in a range from 10 nm to 20 nm, although narrower or wider via structures 118 may be used. As shown in FIG. 3B, the deep vias may be formed to penetrate through the semiconductor material layer 10 and into semiconductor substrate 8. In other embodiments, the via structures 118 may be formed in locations other than between transistor structures 301.

The intermediate structure 300c of FIG. 3C may be formed from the intermediate structure 300b of FIG. 3B by forming an additional layer of the planarization dielectric layer 31A over the via structures 118. First vias 304V may then be formed in the planarization dielectric layer 31A. Thus, as shown in FIG. 3C, a first via layer V1 and a first metal layer M1 may be formed. As indicated in FIG. 3C, the first via layer V1 may represent a top structure of the semiconductor material layer 10 and the first metal layer M1 may be a first layer in a front-side interconnect structure 122 to be formed. In various embodiments, a one or more additional metal lines 304L and vias 304V may be formed over the first via layer V1 and the first metal layer M1. For example, in some embodiments, the resulting front-side interconnect structure may include 10 to 20 interconnect levels formed in 10 to 20 respective front-side dielectric layers.

FIG. 3D is a vertical cross-sectional view of a further intermediate structure 300d that may be used to form the first wafer 102a, according to various embodiments. In this regard, the intermediate structure 300c of FIG. 3C may be inverted (e.g., see FIG. 3D) such that an additional BEOL process may be performed to form a back-side interconnect structure (e.g., see the first bond pad structures 104a formed in the first dielectric layer 124a of FIG. 1). In this regard, a back-side portion of the substrate 8 may be removed by a planarization process, and a plurality of via cavities (not shown) may be formed in a remaining portion of the substrate 8. As shown in FIG. 3D, first back-side vias 310V may then be formed. A first back-side metallization layer 312 including first back-side metal lines 310L may then be formed.

As shown in FIG. 3D, the back-side portion of the substrate 8 including the first back-side vias 310V along with the first back-side metallization layer 312 may form first components of a back-side interconnect structure. In some embodiments, a plurality of additional metal lines and vias may then be formed over the first back-side vias 310V along with the first back-side metallization layer 312 to thereby form additional components of the back-side interconnect structure. For example, in some embodiments, the resulting back-side interconnect structure may include 5 to 10 interconnect levels formed in 5 to 10 respective back-side dielectric layers. The first dielectric layer 124a and the bond pad structures 104a (e.g., see FIG. 1) may then be formed over the back-side interconnect structure (first dielectric layer 124a and first bond pad structures 104a not shown in FIG. 3D).

FIGS. 4A-4F illustrate vertical cross-sectional views of respective intermediate structures (400a, 400b, 400c, 400d, 400e, 400f) that may be used to form the first wafer 102a, according to various embodiments. In this regard, the intermediate structure 400a of FIG. 4A may include a first substrate 8a that may be a semiconductor substrate such as a crystalline silicon substrate or an SOI substrate. The intermediate structure 400b of FIG. 4B may be formed from the intermediate structure 400a by forming a plurality of first electrical circuits (e.g., see CMOS circuits 75 in FIGS. 2A and 2B, FinFET transistors 301 in FIG. 3A, etc.) formed in a first semiconductor material layer 10a of the first substrate 8a.

The intermediate structure 400c of FIG. 4C may be formed from the intermediate structure 400b by forming a via structure 118 and an interconnect structure 122 over the intermediate structure 400b of FIG. 4B. In this regard, the via structure 118 and the interconnect structure 122 may be formed as described above with reference to FIGS. 3A-3C. The third dielectric layer 124c (e.g., see FIG. 1) may then be formed over the interconnect structure 122 and the via structure 118. For clarity of illustration, only a single via structure 118 is shown in FIGS. 1 and 4C. However, as shown in FIGS. 3B-3D, a plurality of via structures 118 may be formed. The via structure(s) may be electrically connected to the plurality of first electrical circuits (75, 301) and to the interconnect structure 122.

The intermediate structure 400d of FIG. 4D may be formed from the intermediate structure 400c by forming an opening 402 in the intermediate structure 400c. The opening 402 may be formed to have various shapes. For example, the opening 402 may be formed as a trench or as a cylindrical opening, etc. The opening 402 may be formed by performing an anisotropic etch process on the intermediate structure 400c of FIG. 4C. In this regard, a patterned photoresist (not shown) may be formed over the intermediate structure 400c and the patterned photoresist may be used as an etch mask during the etching process. In this regard, the etching process may etch a portion of the intermediate structure 400c that is not masked by the patterned photoresist to thereby form the opening 402. As shown in FIG. 4D, the etch process may be performed to etch through the third dielectric layer 124c, through the first semiconductor material layer 10a, and into a portion of the first substrate 8a. A dielectric material (e.g., dielectric material layer 106L shown in FIG. 4E) may then be deposited in the opening 402 to form the first dielectric window structure 106a, as described in greater detail with reference to FIGS. 4E and 4F, below.

The intermediate structure 400e of FIG. 4E may be formed by depositing a dielectric material layer 106L over the intermediate structure 400d of FIG. 4D. In this regard, the dielectric material layer 106L may be formed as a blanket layer and may include various dielectric materials such as silicon oxide. Other suitable dielectric materials are within the contemplated scope of disclosure. The intermediate structure 400f of FIG. 4F may be formed by removing a portion of the dielectric material layer 106L above a top surface of the third dielectric layer 124c. For example, a planarization process (e.g., CMP) may be performed to remove excess portions of the dielectric material layer 106L. The portion of the dielectric material layer 106L that remains in the opening 402 may thereby form the first dielectric window structure 106a.

FIGS. 5A-5C illustrate vertical cross-sectional views of respective intermediate structures (500a, 500b, 500c) that may be used to form the first wafer 102a, according to various embodiments. In this regard, the intermediate structure 500a may be formed by attaching a carrier substrate 110 to the intermediate structure 400f of FIG. 4F. The carrier substrate 110 may be adhered to the intermediate structure 400f using an adhesive 112. The adhesive 112 may be configured to be a temporary adhesive that may be decoupled from the carrier substrate 110 and the intermediate structure 400f by application of heat or UV-light. The intermediate structure 500b of FIG. 5B may be formed from the intermediate structure 500a by removing a back side portion of the first substrate 8a. For example, a grinding process may be performed on a back side of the first substrate 8a to reduce the thickness of the first substrate 8a. As such, the grinding process may remove a sufficient amount of the first substrate 8a such that a bottom surface of the via structure 118 and the first dielectric window structure 106a may be exposed, as shown in FIG. 5B.

The intermediate structure 500c may then be formed by depositing the first dielectric layer 124a over the back side of the first substrate 8a followed by forming the first bond pad structures 104a and the first alignment marks 108a. In this regard, the first dielectric layer 124a may patterned to form openings corresponding to locations at which the first bond pad structures 104a and the first alignment marks 108a are to be formed. A conductive material may then be deposited in the openings to thereby form the first bond pad structures 104a and the first alignment marks 108a. As shown in FIG. 5C, the resulting intermediate structure 500c may include the first wafer 102a bonded to the carrier substrate 110 with the removable adhesive 112.

FIGS. 6A and 6B illustrate vertical cross-sectional views of respective intermediate structures (600a, 600b) that may be used to form the second wafer 102b, and FIG. 6C is a vertical cross-sectional view of the resulting second wafer 102b formed by further processing the intermediate structure 600b of FIG. 6B, according to various embodiments. In this regard, the intermediate structure 600a of FIG. 6A may include a second substrate 8b that may be a semiconductor substrate such as a crystalline silicon substrate or an SOI substrate. The intermediate structure 600b of FIG. 6B may be formed from the intermediate structure 600a by forming a plurality of second electrical circuits (e.g., see CMOS circuits 75 in FIGS. 2A and 2B, FinFET transistors 301 in FIG. 3A, etc.) in a second semiconductor material layer 10b of the second substrate 8b.

The intermediate structure 600c including second wafer 102b shown in FIG. 6C may be formed from the intermediate structure 600b by further processing the intermediate structure 600b of FIG. 6B, according to various embodiments. Such further processing operations may include forming an interconnect structure 122 over the intermediate structure 600b of FIG. 6B. In this regard, the interconnect structure 122 may be formed as described above with reference to FIGS. 2A-3C. The second dielectric layer 124b (e.g., see FIG. 1) may then be formed over the interconnect structure 122. The second dielectric layer 124b may then be patterned and a conductive material may be deposited over the patterned second dielectric layer 124b to thereby form the second bond pad structure 104b and the second alignment marks 108b.

FIG. 7A illustrates an intermediate structure 700a in which the first wafer 102a (e.g., see FIG. 5C) is positioned in proximity to the second wafer 102b (e.g., see FIG. 6C) prior to formation of a wafer-to-wafer bonded structure 100 (e.g., see FIGS. 1 and 7B), according to various embodiments. The intermediate structure 700a may be formed by positioning the first wafer 102a relative to the second wafer 102b such that the first bond pad structures 104a of the first wafer 102a are approximately aligned with second bond pad structures 104b of the second wafer 102b. The optical system 114 may then be used to determine a position of one or more first alignment marks 108a of the first wafer 102a relative to one or more second alignment marks 108b of the second wafer 102b by imaging the one or more first alignment marks 108a and the one or more second alignment marks 108b through the first dielectric window structure 106a formed in the first wafer 102a.

In this regard, imaging the one or more first alignment marks 108a and the one or more second alignment marks 108b may include using the optical system 114 to direct visible light 116 through the first dielectric window structure 106a and observing or recording an image of the one or more first alignment marks 108a and the one or more second alignment marks 108b generated by visible light 116. A relative position of the first wafer 102a and the second wafer 102b may then be adjusted to align the one or more first alignment marks 108a of the first wafer 102a relative to the one or more second alignment marks 108b of the second wafer 102b. A degree to which the relative position of the first wafer 102a and the second wafer 102b may be adjusted may be based on imaging of the one or more first alignment marks 108a and the one or more second alignment marks 108b through the first dielectric window structure 106a. Once the first wafer 102a and the second wafer 102b are aligned relative to one another, a bonding operation may be performed as described in greater detail with reference to FIG. 7B.

FIG. 7B is the wafer-to-wafer bonded structure 100 (e.g., see FIG. 1) formed by bonding the first wafer 102a and the second wafer 102b of FIG. 7A, according to various embodiments. In this regard, the wafer-to-wafer bonded structure 100 may be formed from the intermediate structure 700a of FIG. 7A by placing the first wafer 102a in contact with the second wafer 102b such that the first bond pad structures 104a of the first wafer 102a are contacting the second bond pad structures 104b of the second wafer 102b and by performing a direct bonding process to bond the first wafer 102a to the second wafer 102b. In this regard, the first wafer 102a may be bonded to the second wafer 102b by performing a hybrid bonding process such that direct dielectric-to-dielectric bonds may be formed between the first dielectric layer 124a and the second dielectric layer 124b. Similarly, the hybrid bonding process may generate direct metal-to-metal bonds between the first bond pad structures 104a and the second bond pad structures 104b.

As shown in FIGS. 1 and 7B, the first wafer 102a may be bonded to the second wafer 102b in a face-to-back configuration. In this regard, the first bond pad structures 104a may be configured as back-side bond pad structures 104a formed in a first dielectric layer 124a on a back side of the first substrate 8a of the first wafer 102a, as described with reference to FIG. 5C, above. As such, the back-side bond pad structures 104a may be electrically connected to the via structure 118 that is formed in the first semiconductor material layer 10a and that penetrates through the first substrate 8a. The via structure 118 may also be configured to be electrically connected to the first electrical circuits (75, 301) that are formed in the first semiconductor material layer 10a of the first wafer 102a.

As further shown in FIG. 7B, the second bond pad structures 104b may be configured as front-side bond pad structures 104b formed in the second dielectric layer 124b on a front side of the second wafer 102b. The front-side bond pad structures 104b may be electrically connected to electrical interconnect structures 122 of the second wafer 102b. The first wafer 102a may further include additional front-side electrical interconnect structures 122 formed within a third dielectric layer 124c. The front-side electrical interconnect structures 122 formed within a third dielectric layer 124c may be used to form electrical connections with additional circuit components and/or additional interconnect structures to be formed subsequently.

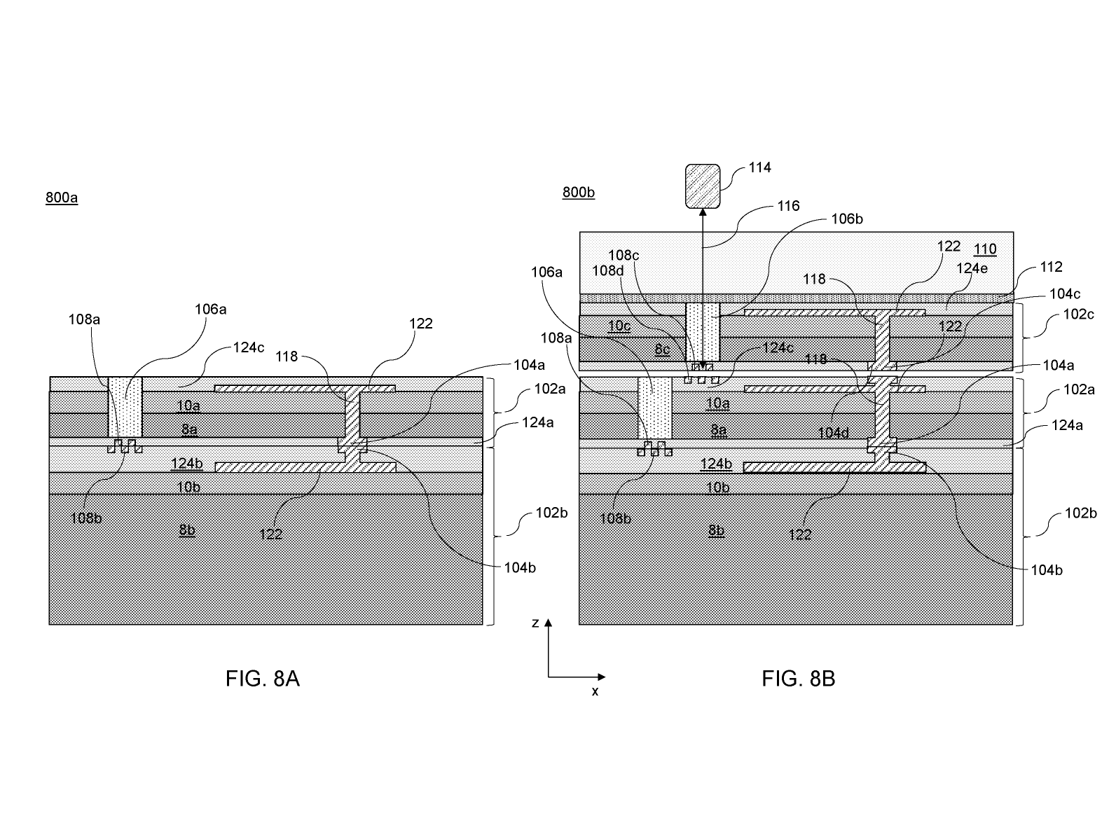

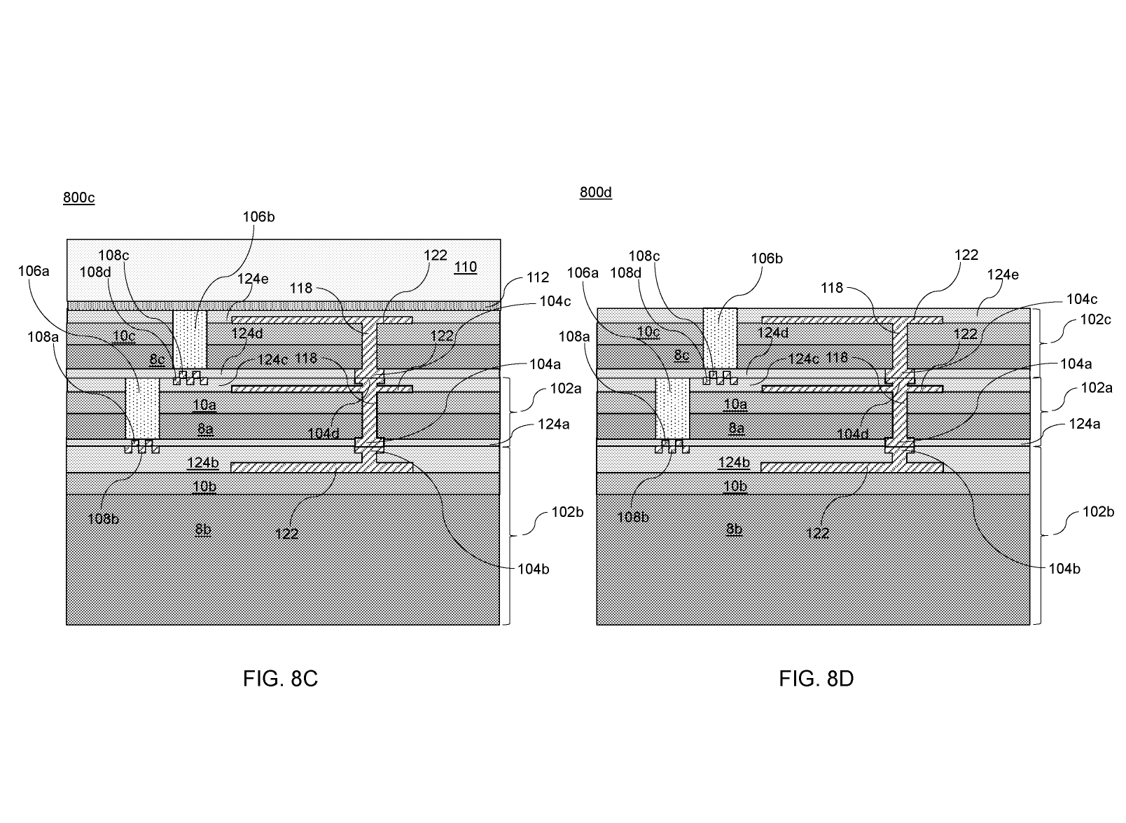

FIGS. 8A and 8B are vertical cross-sectional views of respective intermediate structures (800a, 800b) that may be used in the formation of a further wafer-to-wafer bonded structure, and FIG. 8C is a vertical cross-sectional view of the resulting wafer-to-wafer bonded structure 800c (e.g., see FIG. 8C), according to various embodiments. The intermediate structure 800a may be formed from the wafer-to-wafer bonded structure 100 of FIG. 7B by removing the carrier substrate 110 of the wafer bonded structure 100. In this regard, the adhesive 112 (e.g., see FIG. 7B) may be a removable adhesive 112 that may be deactivated by application of heat or UV-light. As such the carrier substrate 110 may be removed by first deactivating the adhesive 112 followed by removal of the carrier substrate. The resulting intermediate structure 800b may then be used as a starting structure upon which further additional circuit components may be formed. For example, one or more additional wafers may be subsequently bonded to the intermediate structure 800b, as described in greater detail with reference to FIGS. 8B and 8C, below.

FIG. 8B illustrates an intermediate structure 800b in which a third wafer 102c is positioned in proximity to the first wafer 102a prior to formation of a further wafer-to-wafer bonded structure 800c (e.g., see FIG. 8C), according to various embodiments. The third wafer 102c may be similar to the first wafer 102a and may be formed using processes similar to those described with reference to FIGS. 4A-5C, above. In this regard, the third wafer 102c may include third electrical circuits (e.g., see CMOS circuits 75 in FIGS. 2A and 2B, FinFET transistors 301 in FIG. 3A, etc.) that may be formed in a third semiconductor material layer 10c of a third substrate 8c. The third electrical circuits (75, 301) may be electrically connected to third bond pad structures 104c by a via structure 118. As shown in FIG. 8B, the third wafer 102c may include a second dielectric window structure 106b that may be laterally displaced from the first dielectric window structure 106a of the first wafer 102a such as to be non-overlapping in a plan view (i.e., along the z-direction in FIG. 8B).

The third wafer 102c may further include third alignment marks 108c aligned with the second dielectric window structure 106b in the plan view (i.e., along the z-direction in FIG. 8B). As shown in FIG. 8B, the first wafer 102a may further include one or more fourth bond pad structures 104d and one or more fourth alignment marks 108d. As such, the optical system 114 may be used to image the third alignment marks 108c of the third wafer 102c relative to the fourth alignment marks 108d of the first wafer 102a by transmitting and receiving visible light 116 through the second dielectric window structure 106b and observing or recording an image of the one or more third alignment marks 108c and the one or more fourth alignment marks 108d generated by visible light 116. A relative position of the third wafer 102c and the first wafer 102a may then be adjusted to align the one or more third alignment marks 108c of the third wafer 102c relative to the one or more fourth alignment marks 108d of the first wafer 102a. A degree to which a relative position of the third wafer 102c and the first wafer 102a may be adjusted may be based on imaging of the one or more third alignment marks 108c and the one or more fourth alignment marks 108d through the second dielectric window structure 106b. Once the third wafer 102c and the first wafer 102a are aligned relative to one another, a bonding operation may be performed as described in greater detail with reference to FIG. 8C.

FIG. 8C is further wafer-to-wafer bonded structure 800c formed by bonding the third wafer 102c and the first wafer 102a of FIG. 8B, according to various embodiments. In this regard, the wafer-to-wafer bonded structure 800c may be formed from the intermediate structure 800b of FIG. 8B by placing the third wafer 102c in contact with the first wafer 102a such that the third bond pad structures 104c of the third wafer 102c are in contact with the fourth bond pad structures 104d of the first wafer 102a and by performing a direct bonding process to bond the third wafer 102c to the first wafer 102a. In this regard, the third wafer 102c may be bonded to the first wafer 102a by performing a hybrid bonding process such that direct dielectric-to-dielectric bonds may be formed between the third dielectric layer 124c of the first wafer 102a and a fourth dielectric layer 124d of the third wafer 102c. Similarly, the hybrid bonding process may generate direct metal-to-metal bonds between the third bond pad structures 104c and the fourth bond pad structures 104d.

As shown in FIG. 8C, the third wafer 102c may be bonded to the first wafer 102a in a face-to-back configuration. In this regard, the third bond pad structures 104c may be configured as back-side bond pad structures 104c formed in the fourth dielectric layer 124d on a back side of the third substrate 8c of the third wafer 102c. In various embodiments, processes similar to those as described above with reference to FIG. 5C may be used to for the back-side bond pad structures 104c. As such, the back-side bond pad structures 104c may be electrically connected to the via structure 118 that is formed in the third semiconductor material layer 10c and that penetrates through the third substrate 8c. The via structure 118 may also be configured to be electrically connected to the third electrical circuits (75, 301) that are formed in the third semiconductor material layer 10c.

As further shown in FIG. 8C, the fourth bond pad structures 104d may be configured as front-side bond pad structures 104d formed in the third dielectric layer 124c on a front side of the first wafer 102a. The front-side bond pad structures 104d may be electrically connected to electrical interconnect structures 122 of the first wafer 102a. The third wafer 102c may further include additional front-side electrical interconnect structures 122 formed within a fifth dielectric layer 124e. The front-side electrical interconnect structures 122 formed within the fifth dielectric layer 124e may be used to form electrical connections with additional circuit components and/or additional interconnect structures to be formed subsequently.

FIG. 8D is a vertical cross-sectional view of a further intermediate structure 800d that includes the wafer-to-wafer bonded structure 800c of FIG. 8C, according to various embodiments. The intermediate structure 800d may be formed from the wafer-to-wafer bonded structure 800c of FIG. 8C by removing the carrier substrate 110. In this regard, the adhesive 112 (e.g., see FIG. 8C) may be a removable adhesive 112 that may be deactivated by application of heat or UV-light. As such, the carrier substrate 110 may be removed by first deactivating the adhesive 112 followed by removal of the carrier substrate 110. The resulting intermediate structure 800d may then be used as a starting structure upon which further additional circuit components may be formed. For example, one or more additional wafers may be subsequently bonded to the intermediate structure 800d, as described above with reference to FIGS. 8B and 8C.

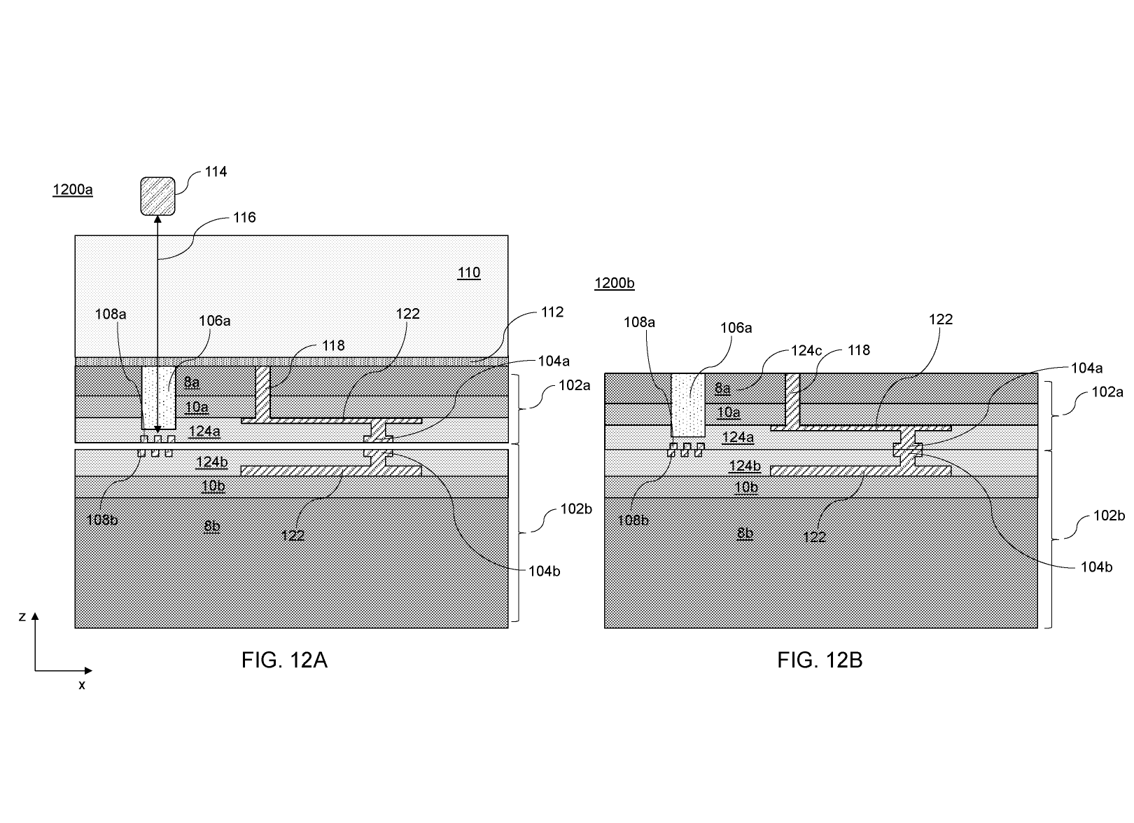

FIGS. 9A -9F illustrate vertical cross-sectional views of respective intermediate structures (900a, 900b, 900c, 900d, 900e, 900f) that may be used to form the first wafer 102a, according to various embodiments. The first wafer 102a, formed according to processes described with reference to FIGS. 9A to 9F, may be used in an embodiment wafer-to-wafer bonded structure 1200b having a face-to-face bonding configuration (e.g., see FIG. 12B). In this regard, the intermediate structure 900a of FIG. 9A may include a first substrate 8a that may be a semiconductor substrate such as a crystalline silicon substrate or an SOI substrate. The intermediate structure 900b of FIG. 9B may be formed from the intermediate structure 900a by forming a plurality of first electrical circuits (e.g., see CMOS circuits 75 in FIGS. 2A and 2B, FinFET transistors 301 in FIG. 3A, etc.) formed in a first semiconductor material layer 10a of the first substrate 8a.

The intermediate structure 900c of FIG. 9C may be formed from the intermediate structure 900b by forming a via structure 118 and an interconnect structure 122 over the intermediate structure 900b of FIG. 9B. In this regard, the via structure 118 and the interconnect structure 122 may be formed as described above with reference to FIGS. 3A-3C. The first dielectric layer 124a may then be formed over the interconnect structure 122 and the via structure 118. For clarity of illustration, only a single via structure 118 is shown in FIG. 9C. However, as shown in FIGS. 3B-3D, a plurality of via structures 118 may be formed. The via structure(s) 118 may be electrically connected to the plurality of first electrical circuits (75, 301) and to the interconnect structure 122.

The intermediate structure 900d of FIG. 9D may be formed from the intermediate structure 900c by forming an opening 402 in the intermediate structure 900c. The opening 402 may be formed to have various shapes. For example, the opening 402 may be formed as a trench or as a cylindrical opening, etc. The opening 402 may be formed by performing an anisotropic etch process on the intermediate structure 900c of FIG. 9C. In this regard, a patterned photoresist (not shown) may be formed over the intermediate structure 900c and the patterned photoresist may be used as an etch mask during the etching process. In this regard, the etching process may etch a portion of the intermediate structure 900c that is not masked by the patterned photoresist to thereby form the opening 402. As shown in FIG. 9D, the etch process may be performed to etch through the first dielectric layer 124a, through the first semiconductor material layer 10a, and into a portion of the first substrate 8a. A dielectric material (e.g., dielectric material layer 106L shown in FIG. 9E) may then be deposited in the opening 402 to form the first dielectric window structure 106a, as described in greater detail with reference to FIGS. 9E and 9F, below.

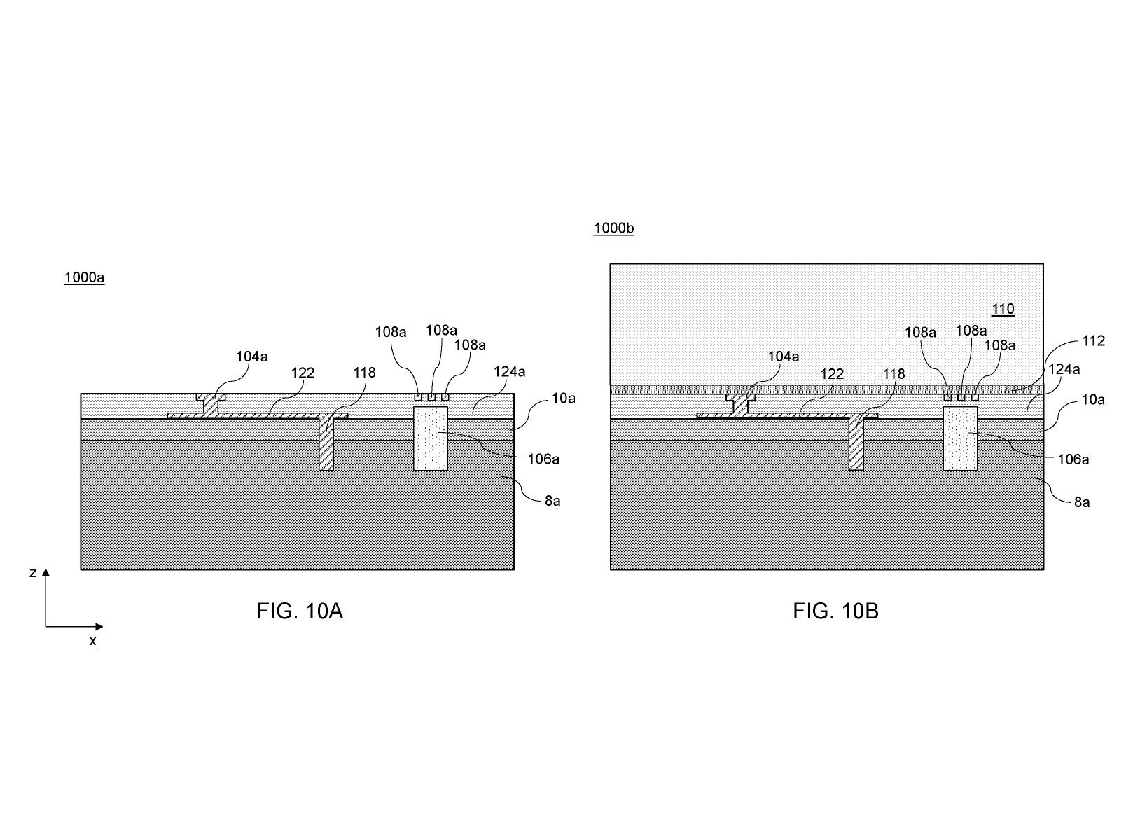

FIG. 10A is a vertical cross-sectional view of a further intermediate structure 1000a that may be formed by further processing the intermediate structure 900f of FIG. 9F, according to various embodiments. Such further processing operations may include forming an interconnect structure 122 over the intermediate structure 900f of FIG. 9F. In this regard, the interconnect structure 122 may be formed as described above with reference to FIGS. 2A-3C. An additional amount of the first dielectric layer 124a may then be formed over the interconnect structure 122. The first dielectric layer 124a may then be patterned and a conductive material may be deposited over the patterned first dielectric layer 124a to thereby form the first bond pad structure 104a and the first alignment marks 108a.

FIG. 10B is a vertical cross-sectional view of a further intermediate structure 1000b that may be used in forming the first wafer 102a, according to various embodiments. In this regard, the intermediate structure 1000b may be formed by attaching a carrier substrate 110 to the intermediate structure 1000a of FIG. 10A. The carrier substrate 110 may be adhered to the intermediate structure 1000a using an adhesive 112 that may be configured to be decoupled from the carrier substrate 110 and the intermediate structure 1000a by application of heat or UV-light.

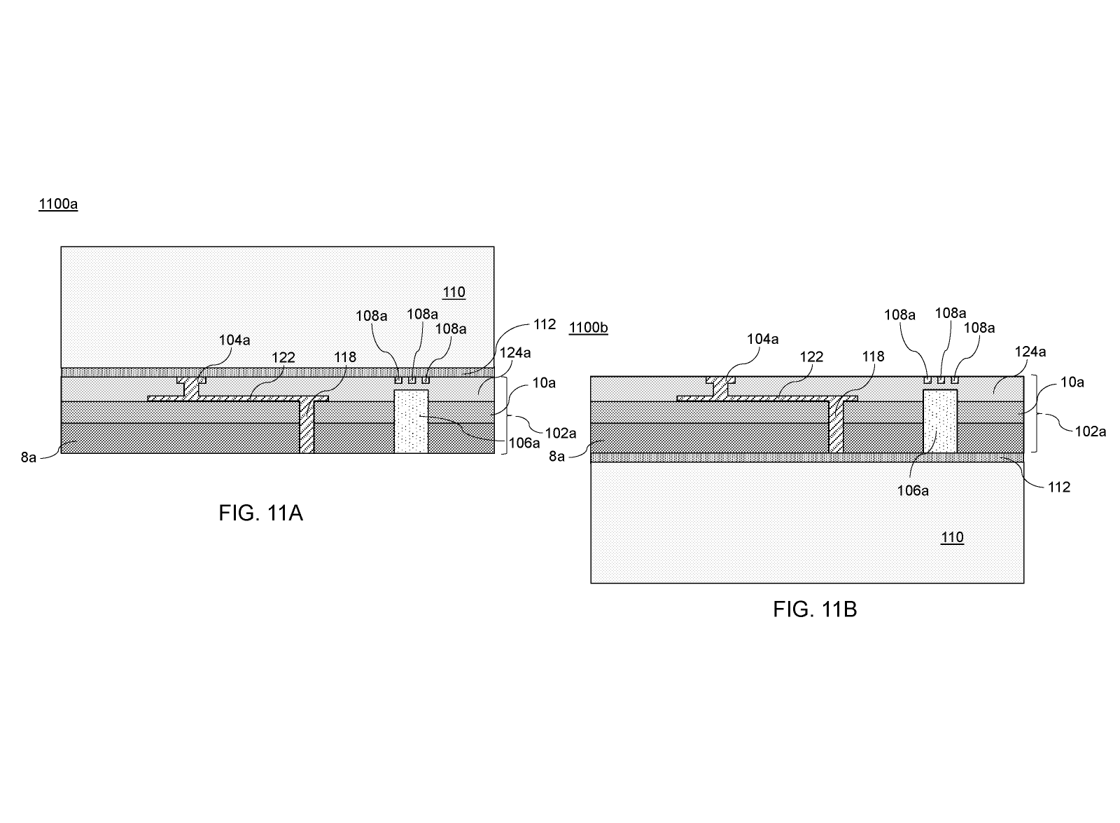

FIGS. 11A and 11B are vertical cross-sectional views of further intermediate structures (1100a, 1100b) that may be used in forming the first wafer 102a, according to various embodiments. The intermediate structure 1100a of FIG. 11A may be formed from the intermediate structure 1000b by removing a backside portion of the first substrate 8a. For example, a grinding process may be performed on a back side of the first substrate 8a to reduce a thickness of the first substrate 8a. As such, the grinding process may remove a sufficient amount of the first substrate 8a such that a bottom surface of the via structure 118 and the first dielectric window structure 106a may be exposed, as shown in FIG. 11A. In this way, the first wafer 102a may be generated.

The intermediate structure 1100b may be formed from the intermediate structure 1100a by attaching a second carrier substrate 110 to the back side of the first wafer 102a (e.g., see FIG. 11B) and by removing the first carrier substrate 110 (e.g., see FIG. 11A) from the front side of the first wafer 102a. As described above, the first carrier substrate 110 (e.g., see FIG. 11A) may be removed by applying heat or UV-light to decouple the adhesive 112. Upon removal of the first carrier substrate 110 of FIG. 11A a front surface of the first wafer 102a may be exposed. As such, the first bond pad structures 104a may be configured as front side bond pad structures 104a. The resulting first wafer 102a may then be bonded to a second wafer 102b to form a wafer-to-wafer bonded structure that has a face-to-face bonding configuration, as described in further detail with reference to FIGS. 12A and 12B, below.

FIG. 12A illustrates an intermediate structure 1200a in which the first wafer 102a (e.g., see FIG. 11B) has been inverted and is positioned in proximity to a second wafer 102b (e.g., see FIG. 6C) prior to forming a wafer-to-wafer bonded structure 1200b (e.g., see FIG. 12B), according to various embodiments. The first wafer 102a may be formed according to processes described with reference to FIGS. 9A-11B, above, and the second wafer 102b may be formed according to processes described with reference to FIGS. 6A- 6C, above. The intermediate structure 1200a may be formed by positioning the first wafer 102a relative to the second wafer 102b such that the first bond pad structures 104a of the first wafer 102a are approximately aligned with second bond pad structures 104b of the second wafer 102b. The optical system 114 may then be used to determine a position of one or more first alignment marks 108a of the first wafer 102a relative to one or more second alignment marks 108b of the second wafer 102b by imaging the one or more first alignment marks 108a and the one or more second alignment marks 108b through the first dielectric window structure 106a formed in the first wafer 102a.

In this regard, imaging the one or more first alignment marks 108a and the one or more second alignment marks 108b may include using the optical system 114 to direct visible light 116 through the first dielectric window structure 106a and observing or recording an image of the one or more first alignment marks 108a and the one or more second alignment marks 108b generated by visible light 116. A relative position of the first wafer 102a and the second wafer 102b may then be adjusted to align the one or more first alignment marks 108a of the first wafer 102a relative to the one or more second alignment marks 108b of the second wafer 102b. A degree to which the relative position of the first wafer 102a and the second wafer 102b may be adjusted may be based on imaging of the one or more first alignment marks 108a and the one or more second alignment marks 108b through the first dielectric window structure 106a. Once the first wafer 102a and the second wafer 102b are aligned relative to one another, a bonding operation may be performed as described in greater detail with reference to FIG. 12B.

FIG. 12B is wafer-to-wafer bonded structure 1200b formed by bonding the first wafer 102a and the second wafer 102b of FIG. 12A, according to various embodiments. In this regard, the wafer-to-wafer bonded structure 1200b may be formed from the intermediate structure 1200a of FIG. 12A by placing the first wafer 102a in contact with the second wafer 102b such that the first bond pad structures 104a of the first wafer 102a are in contact with the second bond pad structures 104b of the second wafer 102b and by performing a direct bonding operation to bond the first wafer 102a to the second wafer 102b. In this regard, the first wafer 102a may be bonded to the second wafer 102b by performing a hybrid bonding process such that direct dielectric-to-dielectric bonds may be formed between the first dielectric layer 124a and the second dielectric layer 124b. Similarly, the hybrid bonding process may generate direct metal-to-metal bonds between the first bond pad structures 104a and the second bond pad structures 104b.

As shown in 12B, the first wafer 102a may be bonded to the second wafer 102b in a face-to-face configuration. In this regard, the first bond pad structures 104a may be configured as front-side bond pad structures 104a formed in the first dielectric layer 124a on a front side of the first wafer 102a, as described with reference to FIG. 10A, above. As such, the front-side bond pad structures 104a may be electrically connected to the via structure 118 that is formed in the first semiconductor material layer 10a and that penetrates through the first substrate 8a. The via structure 118 may also be configured to be electrically connected to the first electrical circuits (75, 301) that are formed in the first semiconductor material layer 10a.

As further shown in FIG. 12B, the second bond pad structures 104b may also be configured as front-side bond pad structures 104b formed in the second dielectric layer 124b on a front side of the second wafer 102b. The front-side bond pad structures 104b may be electrically connected to electrical interconnect structures 122 of the second wafer 102b. After bonding the first wafer 102a to the second wafer 102b, the carrier substrate 110 may be removed. As described above, the carrier substrate 110 may be removed by applying heat or UV-light to the adhesive 112 to decouple the adhesive 112 from the carrier substrate 110 and the wafer-to-wafer bonded structure 1200b. Upon removal of the carrier substrate 110, the resulting wafer-to-wafer bonded structure 1200b may be used as a further intermediate structure in which one or more additional wafers (not shown) may be bonded.

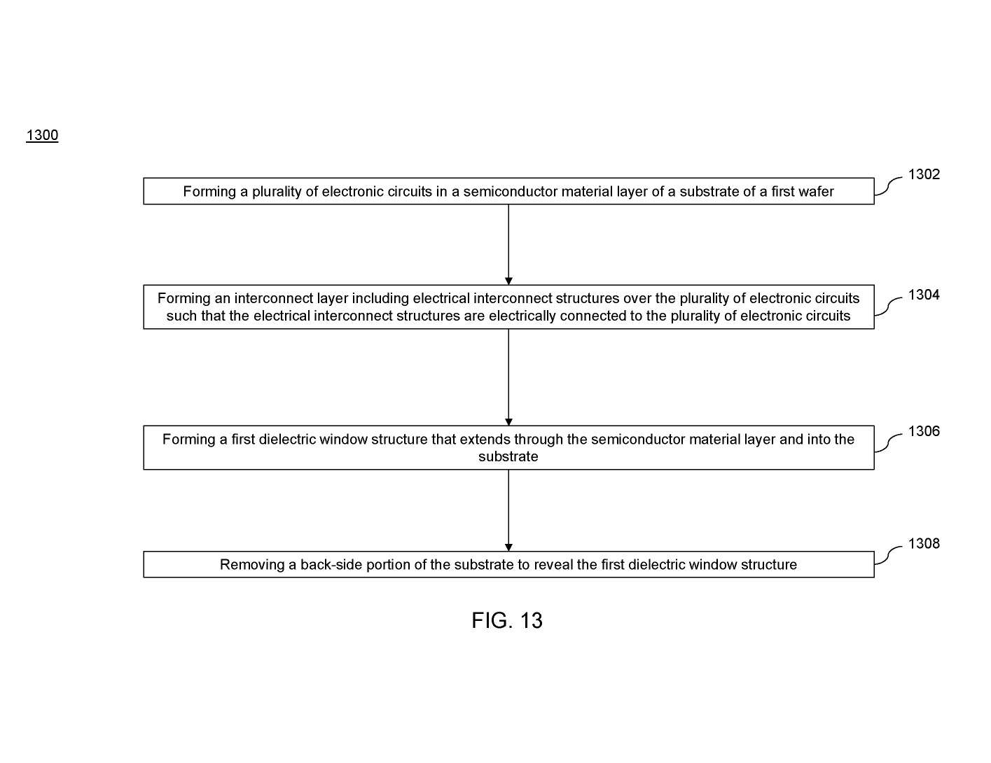

FIG. 13 is a flowchart illustrating operations of a method 1300 of forming a wafer-to-wafer bonded structure (100, 800c, 1200b), according to various embodiments. In operation 1302, the method 1300 may include forming a plurality of electronic circuits (75, 301) in a semiconductor material layer 10a of a substrate 8a of the first wafer 102a. In operation 1304, the method 1300 may include forming an interconnect layer including electrical interconnect structures 122 over the plurality of electronic circuits (75, 301) such that the electrical interconnect structures 122 are electrically connected to the plurality of electronic circuits (75, 301). In operation 1306, the method 1300 may include forming a first dielectric window structure 106a that extends through the first semiconductor material layer 10a and into the substrate 8a. In operation 1308, the method 1300 may include removing a back-side portion of the substrate 8a to reveal the first dielectric window structure 106a (e.g., see FIGS. 5B and 11A).

The method 1300 may further include forming a via structure 118 that is electrically connected to the electrical interconnect structures 122 and extends into the first semiconductor material layer 10a. Further, the operation of removing the back-side portion of the substrate 8a may further reveal the via structure 118. According to operation 1306 of forming the first dielectric window structure 106a, the method 1300 may further include forming an opening 402 that extends through the first semiconductor material layer 10a and into the substrate 8a and filling the opening 402 with a dielectric material 106L that is transparent to visible light 116. According to operation 1306 of forming the first dielectric window structure 106a, the method 1300 may further include forming the first dielectric window structure 106a to have a lateral displacement relative to the via structure 118 such that the first dielectric window structure 106a is non-overlapping with a second dielectric window structure 106b of a second wafer 102b in a plan view (i.e. along the z-direction in FIG. 8B) in a configuration in which the first wafer 102a and the second wafer 102b are aligned relative to one another.

The method 1300 may further include forming one or more back-side bond pad structures 104a on a back side of the substrate 8a such that the one or more back-side bond pad structures 104a are electrically connected to the via structure 118 (e.g., see FIG. 5C). The method 1300 may further include forming one or more back-side alignment marks 108a on the back side of the substrate 8a such that the one or more back-side alignment marks 108a are aligned with the first dielectric window structure 106a in a plan view (i.e. along the z-direction in FIG. 5C). According to the method 1300, the process of forming the one or more back-side bond pad structures 104a and forming the one or more back-side alignment marks 108a may further include depositing a dielectric material 124a on the back side of the substrate 8a and patterning the dielectric material layer 106L to form a patterned dielectric material layer 106L including openings corresponding to respective locations of the one or more back-side bond pad structures 104a and the one or more back-side alignment marks 108a to be formed subsequently. The method 1300 may further include depositing an electrically conducting material over the patterned dielectric material 124a to thereby form the one or more back-side bond pad structures 104a and the one or more back-side alignment marks 108a (e.g., see FIG. 5C).

In other embodiments (e.g., see FIG. 10A), the method 1300 may further include forming one or more front-side bond pad structures 104a on a front side of the first wafer 102a such that the one or more front-side bond pad structures 104a are electrically connected to the electrical interconnect structures 122. The method 1300 may further include forming front-side alignment marks 108a on the front side of the first wafer 102a such that the front-side alignment marks 108a are aligned with the first dielectric window structure 106a in a plan view (e.g., along the z-direction in FIG. 10A).

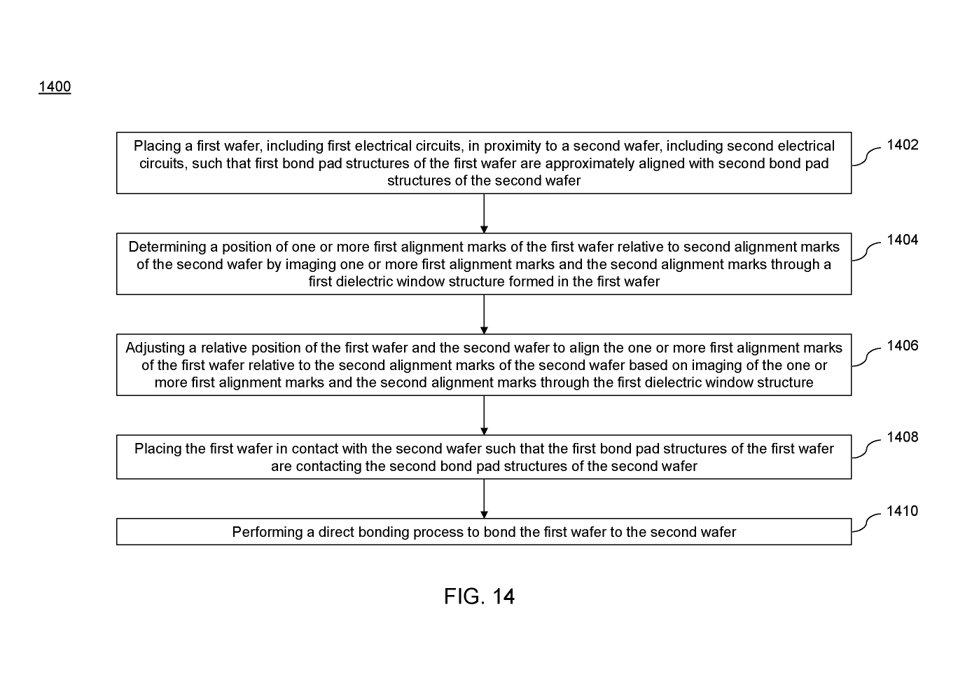

FIG. 14 is a flowchart illustrating operations of a method 1400 of forming a wafer-to-wafer bonded structure (100, 800c, 1200b), according to various embodiments. In operation 1402, the method 1400 may include placing a first wafer 102a, including first electrical circuits, in proximity to a second wafer 102b, including second electrical circuits, such that first bond pad structures 104a of the first wafer 102a are approximately aligned with second bond pad structures 104b of the second wafer 102b (e.g., see FIGS. 7A and 12A). In operation 1404, the method 1400 may include determining a position of one or more first alignment marks 108a of the first wafer 102a relative to one or more second alignment marks 108b of the second wafer 102b by imaging one or more first alignment marks 108a and the second alignment marks 108b through a first dielectric window structure 106a formed in the first wafer 102a. In operation 1406, the method 1400 may include adjusting a relative position of the first wafer 102a and the second wafer 102b to align the one or more first alignment marks 108a of the first wafer 102a relative to the one or more second alignment marks 108b of the second wafer 102b based on imaging of the one or more first alignment marks 108a and the one or more second alignment marks 108b through the first dielectric window structure 106a. In operation 1408, the method 1400 may include placing the first wafer 102a in contact with the second wafer 102b such that the first bond pad structures 104a of the first wafer 102a are contacting the second bond pad structures 104b of the second wafer 102b (e.g., see FIGS. 7B and 12B). In operation 1410, the method 1400 may include performing a direct bonding process to bond the first wafer 102a to the second wafer 102b.

In operation 1404, which includes imaging the one or more first alignment marks 108a and the second alignment marks 108b through the first dielectric window structure 106a, the method 1400 may further include directing visible light 116 through the first dielectric window structure 106a and observing or recording an image of the one or more first alignment marks 108a and the second alignment marks 108b generated by visible light 116. In operation 1408, which includes placing the first wafer 102a in proximity to the second wafer 102b, the method 1400 may further include placing the first wafer 102a and the second wafer 102b in a face-to-back configuration (e.g., see FIGS. 1, 7A, and 7B). In such a face-to-back configuration, first bond pad structures 104a of the first wafer 102a may be back-side bond pad structures 104a formed on a back side of a substrate 8a of the first wafer 102a and second bond pad structures 104b of the second wafer 102b may be front-side bond pad structures 104b formed on a front side of the second wafer 102b such that the front-side bond pad structures 104b are electrically connected to electrical interconnect structures 122 of the second wafer 102b.

In further embodiments (e.g., see FIGS. 12A and 12B), in operation 1408, which includes placing the first wafer 102a in proximity to the second wafer 102b, the method 1400 may further include placing the first wafer 102a and the second wafer 102b in a face-to-face configuration. In such a configuration, the first bond pad structures 104a of the first wafer 102a may be configured as first front-side bond pad structures 104a formed on the first wafer 102a (e.g., see FIG. 10A) and the second bond pad structures 104b of the second wafer 102b may be configured as second front-side bond pad structures 104b formed on the second wafer 102b (e.g., see FIG. 6C).

In further embodiments (e.g., see FIGS. 8B, 8C, and 8D), the method 1400 may further include placing a third wafer 102c, including third electrical circuits (75, 301), in proximity to the first wafer 102a such that one or more third bond pad structures 104c of the third wafer 102c are approximately aligned with one or more fourth bond pad structures 104d of the first wafer 102a. The method 1400 may further include determining a position of one or more third alignment marks 108c of the third wafer 102c relative to one or more fourth alignment marks 108d of the first wafer 102a by imaging the one or more third alignment marks 108c and the one or more fourth alignment marks 108d through a second dielectric window structure 106b formed in the third wafer 102c.

The method 1400 may further include adjusting a relative position of the third wafer 102c and the first wafer 102a to align the one or more third alignment marks 108c of the third wafer 102c relative to the one or more fourth alignment marks 108d of the first wafer 102a based on imaging of the one or more third alignment marks 108c and the one or more fourth alignment marks 108d through the second dielectric window structure 106b. The method 1400 may further include placing the third wafer 102c in contact with the first wafer 102a such that the third bond pad structures 104c of the third wafer 102c are contacting the one or more fourth bond pad structures 104d of the first wafer 102a and performing a direct bonding process to bond the third wafer 102c to the first wafer 102a (e.g., see FIG. 8C). According to the method 1400, adjusting the relative position of the third wafer 102c and the first wafer 102a may further include ensuring that the first dielectric window structure 106a and the second dielectric window structure 106b are non-overlapping in a plan view (e.g., see FIG. 8B).

Referring to all drawings and according to various embodiments of the present disclosure, a wafer-to-wafer bonded structure (100, 800c, 1200b) is provided. The wafer-to-wafer bonded structure (100, 800c, 1200b) may include a first wafer that includes first electrical circuits (75, 301) electrically connected to first bond pad structures 104a, a first dielectric window structure 106a, and first alignment marks 108a aligned with the first dielectric window structure 106a in a plan view (e.g., along the z-direction in FIGS. 1, 5C, and 10A).

In an embodiment, the wafer-to-wafer bonded structure (100, 800c, 1200b) may further include a second wafer 102b including second electrical circuits (75, 301) electrically connected to second bond pad structures 104b, and second alignment marks 108b. In this regard, the first wafer 102a may be directly bonded to the second wafer 102b such that the first bond pad structures 104a are electrically connected to the second bond pad structures 104b and the first alignment marks 108a are aligned relative to the second alignment marks 108b. Further, the first dielectric window structure 106a may be configured to be transparent to visible light 116 allowing imaging of the first alignment marks 108a and the second alignment marks 108b using the visible light 116.

In certain embodiments, the first wafer 102a may be bonded to the second wafer 102b in a face-to-back configuration (e.g., see FIGS. 1 and 7B). In such a configuration, the first bond pad structures 104a may be configured as back-side bond pad structures 104a (e.g., see FIG. 5C) formed on a back side of the first wafer 102a such that the back-side bond pad structures 104a are electrically connected to a via structure 118 formed in a semiconductor material layer 10a that is electrically connected to the first electrical circuits (75, 301). Further, in such a configuration, the second bond pad structures 104b may be front-side bond pad structures 104b (e.g., see FIG. 6C) formed on a front side of the second wafer 102b such that the front-side bond pad structures 104b are electrically connected to electrical interconnect structures 122 of the second wafer 102b.

In certain embodiments, the first wafer 102a may be bonded to the second wafer 102b in a face-to-face configuration (e.g., see FIG. 12B). In such a configuration, the first bond pad structures 104a of the first wafer 102a may be configured as first front-side bond pad structures 104a (e.g., see FIG. 10A) formed on the first wafer 102a and the second bond pad structures 104b of the second wafer 102b may be configured as second front-side bond pad structures 104b formed on the second wafer 102b (e.g., see FIG. 6C).

In further embodiments, the wafer-to-wafer bonded structure (100, 800c, 1200b) may further include a third wafer 102c (e.g., see FIGS. 8C and 8D). The third wafer 102c may include third electrical circuits (75, 301) that may be electrically connect to third bond pad structures 104c, a second dielectric window structure 106b, and third alignment marks 108c aligned with the second dielectric window structure 106b in a plan view (e.g., along the z-direction in FIG. 8B). In such an embodiment, the first wafer 102a may further include one or more fourth bond pad structures 104d and one or more fourth alignment marks 108d. Further, the third wafer 102c may be directly bonded to the first wafer 102a such that the third bond pad structures 104c are directly bonded to fourth bond pad structures 104d of the first wafer 102a, the third alignment marks 108c may be aligned relative to the one or more fourth alignment marks 108d of the first wafer 102a, and the first dielectric window structure 106a and the second dielectric window structure 106b may be laterally displaced from one another such as to be non-overlapping in the plan view as shown, for example, in FIGS. 8B-8D.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A wafer-to-wafer bonded structure, comprising:
a first wafer comprising:
first electrical circuits electrically connected to first bond pad structures;
a first dielectric window structure; and
first alignment marks aligned with the first dielectric window structure in a plan view; and
a second wafer comprising:
second electrical circuits electrically connected to second bond pad structures; and
second alignment marks,
wherein the first wafer is directly bonded to the second wafer such that the first bond pad structures are electrically connected to the second bond pad structures and the first alignment marks are aligned relative to the second alignment marks.

2. The wafer-to-wafer bonded structure of claim 1, wherein the first dielectric window structure is transparent to visible light and is configured to allow imaging of the first alignment marks and the second alignment marks using the visible light.

3. The wafer-to-wafer bonded structure of claim 1, wherein:
the first wafer is bonded to the second wafer in a face-to-back configuration;
the first bond pad structures are back-side bond pad structures formed on a back side of the first wafer and electrically connected to a via structure formed in a semiconductor material layer of the first wafer; and
the second bond pad structures are front-side bond pad structures formed on a front side of the second wafer.

4. The wafer-to-wafer bonded structure of claim 1, wherein:
the first wafer is bonded to the second wafer in a face-to-face configuration;
the first bond pad structures are first front-side bond pad structures formed on the first wafer; and
the second bond pad structures are second front-side bond pad structures formed on the second wafer.

5. The wafer-to-wafer bonded structure of claim 1, wherein the first wafer is bonded to the second wafer such that direct dielectric-to-dielectric bonds are formed between a first dielectric layer of the first wafer and a second dielectric layer of the second wafer, and direct metal-to-metal bonds are formed between the first bond pad structures and the second bond pad structures.

6. The wafer-to-wafer bonded structure of claim 1, wherein the first dielectric window structure comprises silicon dioxide.

7. The wafer-to-wafer bonded structure of claim 1, wherein the first wafer further comprises a via structure formed in a first semiconductor material layer that penetrates through a first substrate of the first wafer, and wherein the via structure is electrically connected to the first electrical circuits and to the first bond pad structures.

8. A wafer for use in a wafer-to-wafer bonded structure, the wafer comprising:
a substrate comprising a semiconductor material layer having a plurality of electrical circuits formed therein;
bond pad structures electrically connected to the plurality of electrical circuits;
a dielectric window structure extending through the semiconductor material layer; and
alignment marks aligned with the dielectric window structure in a plan view.

9. The wafer of claim 8, wherein the dielectric window structure is transparent to visible light.

10. The wafer of claim 8, further comprising a via structure formed in the semiconductor material layer and penetrating through the substrate, wherein the via structure is electrically connected to the plurality of electrical circuits and to the bond pad structures.

11. The wafer of claim 10, wherein the via structure is formed in a shallow trench isolation structure in a region between transistor structures of the plurality of electrical circuits.

12. The wafer of claim 8, further comprising an interconnect structure over the semiconductor material layer, wherein the interconnect structure comprises a plurality of metal lines and vias formed in a plurality of dielectric layers.

13. The wafer of claim 8, wherein the bond pad structures and the alignment marks are formed on a back side of the substrate after removal of a back-side portion of the substrate that reveals the dielectric window structure.

14. The wafer of claim 8, wherein the bond pad structures and the alignment marks are formed on a front side of the wafer.

15. A semiconductor structure, comprising:
a first wafer comprising first electrical circuits formed in a first semiconductor material layer of a first substrate, wherein the first electrical circuits are electrically connected to first bond pad structures;
a first dielectric window structure extending through the first semiconductor material layer and into the first substrate;
first alignment marks aligned with the first dielectric window structure in a plan view;
a second wafer comprising second electrical circuits formed in a second semiconductor material layer of a second substrate, wherein the second electrical circuits are electrically connected to second bond pad structures, and wherein the first wafer is directly bonded to the second wafer such that the first bond pad structures are electrically connected to the second bond pad structures; and
a third wafer comprising third electrical circuits electrically connected to third bond pad structures, a second dielectric window structure, and third alignment marks aligned with the second dielectric window structure in a plan view, wherein the third wafer is directly bonded to the first wafer such that the third bond pad structures are electrically connected to fourth bond pad structures of the first wafer, and wherein the first dielectric window structure and the second dielectric window structure are laterally displaced from one another so as to be non-overlapping in the plan view.

16. The semiconductor structure of claim 15, wherein the first dielectric window structure and the second dielectric window structure each comprise a dielectric material that is transparent to visible light.

17. The semiconductor structure of claim 15, wherein the first wafer comprises a via structure formed in the first semiconductor material layer and penetrating through the first substrate, wherein the via structure is electrically connected to the first electrical circuits and to the first bond pad structures.

18. The semiconductor structure of claim 15, wherein the third wafer is bonded to the first wafer in a face-to-back configuration, the third bond pad structures are back-side bond pad structures formed on a back side of the third wafer, and the fourth bond pad structures are front-side bond pad structures formed on a front side of the first wafer.

19. The semiconductor structure of claim 15, wherein the first wafer is bonded to the second wafer in a face-to-face configuration.

20. The semiconductor structure of claim 15, wherein the first electrical circuits comprise fin field effect transistors (FinFETs) formed in the first semiconductor material layer.
